(19) United States
(12) Patent Application Publication
(10) Pub. No.: US 2025/0282915 A1
(43) Pub. Date: Sep. 11, 2025

(54) METHOD FOR FORMING CURED FILM, METHOD FOR MANUFACTURING IMPRINT MOLD SUBSTRATE, METHOD FOR MANUFACTURING IMPRINT MOLD, METHOD FOR MANUFACTURING RELIEF STRUCTURE, METHOD FOR FORMING PATTERN, METHOD FOR FORMING HARD MASK, METHOD FOR FORMING INSULATING FILM, AND METHOD FOR MANUFACTURING SEMICONDUCTOR DEVICE

(71) Applicant: DAI NIPPON PRINTING CO., LTD., Tokyo (JP)

(72) Inventors: Kouji YOSHIDA, Tokyo (JP); Hirokazu ODA, Tokyo (JP); Yasuhiro OOKAWA, Tokyo (JP); Hiroaki SATO, Tokyo (JP); Takaharu NAGAI, Tokyo (JP); Katsutoshi SUZUKI, Tokyo (JP)

(73) Assignee: DAI NIPPON PRINTING CO., LTD., Tokyo (JP)

(21) Appl. No.: 18/852,969

(22) PCT Filed: Mar. 24, 2023
(86) PCT No.: PCT/JP2023/011841

§ 371 Date: Sep. 30, 2024

(30) Foreign Application Priority Data
Mar. 31, 2022 (JP) 2022-058472

(51) Int. Cl. C08G 77/38; C08G 77/06; C08J 3/24; C08J 3/28; C08J 5/18; G03F 7/00; G03F 7/075; H01L 21/02; H01L 21/027

(52) U.S. Cl. CPC C08G 77/38; C08G 77/06; C08J 3/24; C08J 3/28; C08J 5/18; G03F 7/0002; G03F 7/0757; H01L 21/02118; H01L 21/0274

(57) ABSTRACT

The method for forming a cured film can form, by a more convenient method, a cured film that can be used as, for instance, a protective film. The method for forming a cured film contains a step of supplying, to a substrate, a curable resin containing a polymerization initiator, a reactive crosslinking agent, and a polymerizable compound having in the molecule a siloxane bond and at least one polymerizable functional group; a step of curing the curable resin; and a step of forming a cured film by executing a plasma treatment or an oxidation treatment on the cured curable resin to decompose an organic component contained in the curable resin and cause a siloxane polymerization part to remain.

### TECHNICAL FIELD

The present disclosure relates to a method for forming a cured film, a method for manufacturing an imprint mold substrate, a method for manufacturing an imprint mold, a method for manufacturing a relief structure, a method for forming a pattern, a method for forming a hard mask, a method for forming an insulating film, and a method for manufacturing a semiconductor device.

### BACKGROUND ART

Nanoimprint lithography is known as a technology for the transfer and formation of microfine patterns, for example, in the production of devices for semiconductors. Nanoimprint lithography is a technology in which an imprint mold, which has a microfine relief shape-bearing transfer pattern formed in nanoimprint lithography surface, is brought into contact with a resin that has been supplied onto a transfer-target substrate, e.g., a semiconductor wafer, and in which this resin is then cured, thereby transferring to the resin the relief shape of the transfer pattern of the imprint mold. As the nanoimprint lithographic method, are used a thermal imprint method, in which the relief shape of the transfer pattern is transferred to the resin by using thermal energy, and a photoimprint method, in which the resin is cured by exposure to light. The photoimprint method, which is not subject to the effects of heat-induced expansion and contraction, is mainly used in applications where a high alignment accuracy is required.

With regard to the imprint mold used in the nanoimprint lithography, a mesa-shaped step structure is disposed on a main surface of a base, such that only a prescribed region where the relief shape-bearing transfer pattern is formed (the pattern region) will come into contact with the resin that has been supplied onto the transfer-target substrate, and the transfer pattern is formed on the upper surface of the mesa-shaped step structure. The upper surface of the mesa-shaped step structure then becomes the pattern region in an imprint mold having such a structure. The step height of the mesa-shaped step structure (the height from the main surface of the base to the upper surface of the step structure) is determined by, for instance, the mechanical accuracy of the imprint apparatus being used, but is generally about 30 μm.

When the pattern density of the transfer pattern on the imprint mold is increased, the area of adhesion between the imprint mold and resin is then increased, and as a consequence a force that opposes the frictional force between these two is required when the imprint mold and resin are released from each other. In particular, a large force is required for release in the case of transfer patterns for semiconductor applications due to a small size (dimensions) and high pattern density thereof. The following method is therefore known: a recess is formed in the back side of the imprint mold (the opposite side to the surface where the transfer pattern is formed), which facilitates bending by reducing the template thickness of the prescribed region where the transfer pattern is formed (region containing the pattern region); during release, the pattern region of the imprint mold is bent into a convex shape toward the side of the transfer-target substrate and a sequential partial release is carried out from the outer edge of the transfer region.

In the photoimprint method, in order to suppress unintentional curing of the resin located in nontransfer regions, i.e., regions outside the region that transfers the transfer pattern, it has been proposed that a second step structure be formed above the first step structure of the imprint mold and that a light-blocking area be disposed in the nonpattern area (a location different from the transfer pattern region), i.e., the region outside the second step structure, of the upper surface of the first step structure (refer to PTL 1).

### CITATION LIST

### Patent Literature

[PTL 1] Japanese Patent Application Laid-open No. 2018-56545
[PTL 2] WO 2020/203472

### SUMMARY OF INVENTION

### Technical Problem

An imprint mold having a first step structure and a second step structure and having a light-blocking area disposed in a nonpattern area (a location different from the transfer pattern region) is manufactured by, for example, preparing an imprint mold substrate, in which a second step structure is disposed on a first step structure, and forming a transfer pattern in the transfer pattern region, and subsequently forming a light-blocking area in a nonpattern area (refer to PTL 1). When a transfer pattern is formed in the transfer pattern region of an imprint mold substrate having a first step structure and a second step structure after the light-blocking area has been disposed in a nonpattern area of the imprint mold substrate, damage may end up being introduced into the light-blocking area in, for example, the etching step and cleaning step in the process of manufacturing this imprint mold. As a consequence, the concern arises that the light-blocking area in the manufactured imprint mold will be unable to exhibit a desired function. The suppression of damage to the light-blocking area through the formation of a protective film on the light-blocking area has been considered in order to solve this problem. However, steps such as, for example, sputtering, patterning, and so forth, must be implemented in order to form a protective film on the light-blocking area that is disposed only in a nonpattern area of, for example, an imprint mold substrate, and the step of forming the light-blocking area is then complex.

Considering the aforementioned problem, objects of the present disclosure are to provide: a method for forming a cured film that can form, using a simpler and more convenient method, a cured film that can be used as, for example, a protective film as described in the preceding; a method for manufacturing an imprint mold substrate that uses this method for forming a cured film d; a method for manufacturing an imprint mold; a method for manufacturing a relief structure; a method for forming a pattern; a method for forming a hard mask; a method for forming an insulating film; and a method for manufacturing a semiconductor device.

### Solution to Problem

In order to achieve this purpose, there is provided, as a first embodiment of the present disclosure, a method for forming a cured film, the method including: a step of supplying, to a substrate, a curable resin containing a polymerization initiator, a reactive crosslinking agent, and a polymerizable compound having in the molecule a siloxane bond and at least one polymerizable functional group; a step of curing the curable resin; and a step of forming a cured film by executing a plasma treatment or an oxidation treatment on the cured curable resin to decompose an organic component contained in the curable resin and cause a siloxane polymerization part to remain.

The polymerizable compound may have a spherical structure, with the siloxane polymerization part being at the center and the polymerizable functional group extending in an outward direction.

Of oxygen atoms bonded to silicon atoms contained in the polymerizable compound, proportion of oxygen atoms bonded to a single silicon atom may be not more than 10 mol %, and the curable resin may substantially not contain a solvent and may have a viscosity of not more than 20 cPs.

A content of the reactive crosslinking agent contained in the curable resin may be 49 mass % to 79 mass %.

The step of curing the curable resin may include a contact step of bringing a mold into proximity to the substrate and deploying the curable resin between the substrate and the mold to form a shape-receiving resin layer; a curing step of curing the shape-receiving resin layer; and a release step of separating the mold from the cured shape-receiving layer.

An amount of the curable resin supplied to the substrate can be determined based on formula (1) below, which shows relationship among thickness T₀ of the shape-receiving resin layer, thickness T of the cured film, and decomposition treatment time t for decomposition of the organic component.

$$\begin{matrix}[ Math . 1 ] & \\ T = {T}_{0} - {\int }_{0}^{t} {Ab}^{ct} dt \to α t & ( 1 )\end{matrix}$$

In formula (1), Ab^{ct} represents “the decrement per unit time in the film thickness of the shape-receiving resin layer, in which decrement changes in accordance with the decomposition treatment time t in the initial stage of the organic component decomposition treatment”; at represents “the decrement per unit time in the film thickness of the shape-receiving resin layer, in which decrement substantially does not change in accordance with the decomposition treatment time t”; A represents “the film thickness decrement in the shape-receiving resin layer per unit time in the initial stage of the organic component decomposition treatment”; b and c are “coefficients that represent the decline as an exponential function in the film thickness of the shape-receiving resin layer”; and b>1 and c<0.

A cured film formation region, where the cured film is formed, and a non-cured-film-formation region, where the cured film is not formed, may be established on the substrate; the curable resin may be supplied to the cured film formation region in an amount determined so that the thickness T of the cured film based on formula (1) exceeds 0; and the curable resin may be supplied to the non-cured-film-formation region in an amount determined so that the thickness T of the cured film based on formula (1) is not greater than 0.

The mold can have a recess part-containing relief structure; the shape-receiving resin layer can have a transfer structure that contains a protruding part where the recess part of the relief structure has been transferred, and can have a residual film part; and the amount of the curable resin to be supplied to the substrate can be determined based on the depth of the recess part of the relief structure, the thickness of the residual film part, and formula (1).

The mold may have a relief structure in which the minimum dimension is not more than 100 nm; the shape-receiving layer may have a transfer structure where the relief structure has been transferred, and a cured film having a pattern with a dimension smaller than the minimum dimension of the relief structure may be formed; the substrate may have a first surface and a second surface located on an opposite side to the first surface and may have, at least at the first surface, at least one material layer constituted of material different from material of the substrate; and the curable resin may be supplied onto the material layer.

In an embodiment of the present disclosure, there is provided a cured film formed by the aforementioned method for forming a cured film, wherein, in a compositional distribution along a thickness direction of the cured film, the cured film has a concentration gradient in which silicon (Si) atom concentration is highest in the vicinity of the surface of the cured film and silicon (Si) atom concentration is lowest in the vicinity of the substrate.

The compositional distribution along the thickness direction of the cured film may have a concentration distribution in which carbon (C) atom concentration is lowest in the vicinity of the surface of the cured film and carbon (C) atom concentration is highest in the vicinity of the substrate.

An embodiment of the present disclosure provides a method for manufacturing an imprint mold substrate, the method including a step of preparing a multistep mold substrate provided with a base having a first surface and a second surface located on an opposite side to the first surface, a first step structure that protrudes from the first surface of the base, a second step structure that protrudes from an upper surface of the first step structure, and a light-blocking film that is located on an upper surface of the first step structure; a step of supplying, onto the light-blocking film and onto an upper surface of the second step structure, a curable resin containing a polymerization initiator, a reactive crosslinking agent, and a polymerizable compound having in the molecule a siloxane bond and at least one polymerizable functional group, to form a first curable resin layer on the light-blocking film and a second curable resin layer on the upper surface of the second step structure, and then curing the first curable resin layer and the second curable resin layer; and a step of executing a plasma treatment or oxidation treatment on the cured first curable resin layer and second curable resin layer, to decompose an organic component contained in the curable resins and cause a siloxane polymerization part to remain, thereby forming a protective layer on the light-blocking layer and removing the second curable resin layer, wherein a thickness of the second curable resin layer is smaller than a thickness of the first curable resin layer and is a thickness of a size that can be removed during formation of the protective film.

This method may include a step of forming a light-blocking material layer on the upper surface of the second step structure of the multistep mold substrate, and, after removal of the second curable resin layer, removing the light-blocking material layer by etching.

An embodiment of the present disclosure provides a method for manufacturing an imprint mold, wherein this method includes: a step of forming a first hard mask layer on the protective film of the imprint mold substrate that has been manufactured by the method described above, and forming a second hard mask layer on the upper surface of the second step structure; a step of forming a mask pattern on the second hard mask layer; a step of etching the second hard mask layer by using the mask pattern as a mask, to form a hard mask pattern on the upper surface of the second step structure and remove the first hard mask layer; and a step of etching the upper surface of the second step structure by using the hard mask pattern as a mask, to form a relief pattern on the upper surface of the second step structure and remove the protective film.

An embodiment of the present disclosure provides a method for manufacturing a relief structure, the method including: a step of preparing a substrate having a first surface and a second surface located on an opposite side to the first surface; a step of forming, on the first surface, a protrusion pattern-bearing core material pattern; a step of supplying, onto the core material pattern, a curable resin containing a polymerization initiator, a reactive crosslinking agent, and a polymerizable compound having in the molecule a siloxane bond and at least one polymerizable functional group; a step of bringing a template into contact with the curable resin supplied onto the core material pattern and effecting curing, to form a curable resin layer that coats a top and side wall of the protrusion pattern of the core material pattern and coats the first surface that is exposed from between adjacent protrusion patterns; a step of executing a plasma treatment or oxidation treatment on a part, of the curable resin layer, that coats the side wall of the protrusion pattern, to decompose an organic component contained in the curable resin while causing a siloxane polymerization part to remain, also while removing the part that coats the top of the protrusion pattern and removing the part that coats the first surface exposed from between adjacent protrusion patterns; and a step of removing the core material pattern.

An embodiment of the present disclosure provides a method for forming a pattern, the method including: a step of preparing a substrate having a first surface and a second surface located on an opposite side to the first surface; a step of intermittently dripping, on the first surface of the substrate, a curable resin containing a polymerization initiator, a reactive crosslinking agent, and a polymerizable compound having in the molecule a siloxane bond and at least one polymerizable functional group; a step of curing the intermittently dripped curable resin; and a step of executing a plasma treatment or an oxidation treatment on the cured curable resin to decompose an organic component contained in the curable resin and cause a siloxane polymerization part to remain, thereby forming a cured film pattern.

An embodiment of the present disclosure provides a method for forming a pattern, the method including: a step of preparing a substrate having a first surface and a second surface located on an opposite side to the first surface; a step of supplying, to the first surface of the substrate, a curable resin containing a polymerization initiator, a reactive crosslinking agent, and a polymerizable compound having in the molecule a siloxane bond and at least one polymerizable functional group; a step of forming a shape-receiving resin layer by bringing a mold into proximity to the substrate and curing the curable resin deployed between the substrate and the mold; a step of separating the mold from the shape-receiving resin layer; a step of forming, on the shape-receiving resin layer, a resist layer that has a thickness distribution; a step of forming a resin pattern by etching the shape-receiving resin layer by using the resist layer as a mask; and a step of forming a cured film pattern by executing a plasma treatment or oxidation treatment on the resin pattern to decompose an organic component contained in the curable resin and cause a siloxane polymerization part to remain.

An embodiment of the present disclosure provides a method of forming a hard mask in an arbitrary region on a substrate on which a metal film has been formed, the method including: a step of supplying, onto the metal film, a curable resin containing a polymerization initiator, a reactive crosslinking agent, and a polymerizable compound having in the molecule a siloxane bond and at least one polymerizable functional group; a step of forming a shape-receiving resin layer by bringing a mold into proximity to the substrate and curing the curable resin deployed between the substrate and the mold; and a step of forming a hard mask by executing a plasma treatment or oxidation treatment on the shape-receiving resin layer to decompose an organic component contained in the curable resin and cause a siloxane polymerization part to remain.

An embodiment of the present disclosure provides a method of forming an insulating film in an insulating film formation region on a substrate, the method including: a step of supplying, to the insulating film formation region, a curable resin containing a polymerization initiator, a reactive crosslinking agent, and a polymerizable compound having in the molecule a siloxane bond and at least one polymerizable functional group; a step of curing the curable resin; and a step of forming the insulating film by executing a plasma treatment or oxidation treatment on the cured curable resin to decompose an organic component contained in the curable resin and cause a siloxane polymerization part to remain.

An embodiment of the present disclosure provides a method of manufacturing a semiconductor device having a structure in which, on a first surface side of a substrate having a first surface and a second surface located on an opposite side thereto, a semiconductor layer, an insulating film, and wiring are stacked in this sequence, the method including: a step of forming, on the first surface, the semiconductor layer having source drain regions containing a contact part that contacts the wiring; and a step of forming the insulating film by the aforementioned method on the channel region and a region that excludes the contact parts.

### Advantageous Effects of Invention

The present disclosure can provide a method for forming a cured film that can form, using a simpler and more convenient method, a cured film that can be used as, for example, a protective film as described in the preceding; a method for manufacturing an imprint mold substrate that uses this method for forming a cured film; a method for manufacturing an imprint mold; a method for manufacturing a relief structure; a method for forming a pattern; a method for forming a hard mask; a method for forming an insulating film; and a method for manufacturing a semiconductor device.

### BRIEF DESCRIPTION OF DRAWINGS

FIG. 1A is a sectioned end surface that schematically shows a step in the method for forming a cured film according to an embodiment of the present disclosure.

FIG. 1B is a sectioned end surface that schematically shows a step that follows FIG. 1A, which step is a step in the method for forming a cured film according to an embodiment of the present disclosure.

FIG. 1C is a sectioned end surface that schematically shows a step that follows FIG. 1B, which step is a step in the method for forming a cured film according to an embodiment of the present disclosure.

FIG. 1D is a sectioned end surface that schematically shows a step that follows FIG. 1C, which step is a step in the method for forming a cured film according to an embodiment of the present disclosure.

FIG. 2A is a sectioned end surface that schematically shows a step in another implementation of the method for forming a cured film according to an embodiment of the present disclosure.

FIG. 2B is a sectioned end surface that schematically shows a step that follows FIG. 2A, which step is a step in another implementation of the method for forming a cured film according to an embodiment of the present disclosure.

FIG. 2C is a sectioned end surface that schematically shows a step that follows FIG. 2B, which step is a step in another implementation of the method for forming a cured film according to an embodiment of the present disclosure.

FIG. 2D is a sectioned end surface that schematically shows a step that follows FIG. 2C, which step is a step in another implementation of the method for forming a cured film according to an embodiment of the present disclosure.

FIG. 3A is a sectioned end surface that schematically shows a step in the method for manufacturing an imprint mold substrate according to an embodiment of the present disclosure.

FIG. 3B is a sectioned end surface that schematically shows a step that follows FIG. 3A, which step is a step in the method for manufacturing an imprint mold substrate according to an embodiment of the present disclosure.

FIG. 3C is a sectioned end surface that schematically shows a step that follows FIG. 3B, which step is a step in the method for manufacturing an imprint mold substrate according to an embodiment of the present disclosure.

FIG. 3D is a sectioned end surface that schematically shows a step that follows FIG. 3C, which step is a step in the method for manufacturing an imprint mold substrate according to an embodiment of the present disclosure.

FIG. 3E is a sectioned end surface that schematically shows a step that follows FIG. 3D, which step is a step in the method for manufacturing an imprint mold substrate according to an embodiment of the present disclosure.

FIG. 3F is a sectioned end surface that schematically shows a step that follows FIG. 3E, which step is a step in the method for manufacturing an imprint mold substrate according to an embodiment of the present disclosure.

FIG. 4A is a sectioned end surface that schematically shows a step in the method for manufacturing an imprint mold according to an embodiment of the present disclosure.

FIG. 4B is a sectioned end surface that schematically shows a step that follows FIG. 4A, which step is a step in the method for manufacturing an imprint mold according to an embodiment of the present disclosure.

FIG. 4C is a sectioned end surface that schematically shows a step that follows FIG. 4B, which step is a step in the method for manufacturing an imprint mold according to an embodiment of the present disclosure.

FIG. 4D is a sectioned end surface that schematically shows a step that follows FIG. 4C, which step is a step in the method for manufacturing an imprint mold according to an embodiment of the present disclosure.

FIG. 4E is a sectioned end surface that schematically shows a step that follows FIG. 4D, which step is a step in the method for manufacturing an imprint mold according to an embodiment of the present disclosure.

FIG. 4F is a sectioned end surface that schematically shows a step that follows FIG. 4E, which step is a step in the method for manufacturing an imprint mold according to an embodiment of the present disclosure.

FIG. 5A is a sectioned end surface that schematically shows a step in the method for manufacturing a relief structure according to an embodiment of the present disclosure.

FIG. 5B is a sectioned end surface that schematically shows a step that follows FIG. 5A, which step is a step in the method for manufacturing a relief structure according to an embodiment of the present disclosure.

FIG. 5C is a sectioned end surface that schematically shows a step that follows FIG. 5B, which step is a step in the method for manufacturing a relief structure according to an embodiment of the present disclosure.

FIG. 5D is a sectioned end surface that schematically shows a step that follows FIG. 5C, which step is a step in the method for manufacturing a relief structure according to an embodiment of the present disclosure.

FIG. 5E is a sectioned end surface that schematically shows a step that follows FIG. 5D, which step is a step in the method for manufacturing a relief structure according to an embodiment of the present disclosure.

FIG. 6A is a plan view of the step shown in FIG. 5A, which step is a step in the method for manufacturing a relief structure according to an embodiment of the present disclosure.

FIG. 6B is a plan view of the step shown in FIG. 5B, which step is a step in the method for manufacturing a relief structure according to an embodiment of the present disclosure.

FIG. 6C is a plan view of the step shown in FIG. 5C, which step is a step in the method for manufacturing a relief structure according to an embodiment of the present disclosure.

FIG. 6D is a plan view of the step shown in FIG. 5D, which step is a step in the method for manufacturing a relief structure according to an embodiment of the present disclosure.

FIG. 6E is a plan view of the step shown in FIG. 5E, which step is a step in the method for manufacturing a relief structure according to an embodiment of the present disclosure.

FIG. 7A is a sectioned end surface that schematically shows a step in the method for forming a pattern according to an embodiment of the present disclosure.

FIG. 7B is a sectioned end surface that schematically shows a step that follows FIG. 7A, which step is a step in the method for forming a pattern according to an embodiment of the present disclosure.

FIG. 8A is a sectioned end surface that schematically shows a step in another implementation of the method for forming a pattern according to an embodiment of the present disclosure.

FIG. 8B is a sectioned end surface that schematically shows a step that follows FIG. 8A, which step is a step in another implementation of the method for forming a pattern according to an embodiment of the present disclosure.

FIG. 8C is a sectioned end surface that schematically shows a step that follows FIG. 8B, which step is a step in another implementation of the method for forming a pattern according to an embodiment of the present disclosure.

FIG. 9A is a sectioned end surface that schematically shows a step in the method for manufacturing a semiconductor device according to an embodiment of the present disclosure.

FIG. 9B is a sectioned end surface that schematically shows a step that follows FIG. 9A, which step is a step in the method for manufacturing a semiconductor device according to an embodiment of the present disclosure.

FIG. 10 is a graph that shows the results of Example 1, Reference Example 1, and Reference Example 2.

### DESCRIPTION OF EMBODIMENTS

Embodiments of the present disclosure will be described with reference to the drawings.

In order to facilitate understanding, the shape, scale, longitudinal and lateral dimensions, and so forth of individual components in these drawings may be modified from actuality or may be exaggerated. In this Description, numerical value ranges given using a hyphen (“-”) or “to” indicate ranges that include the numerical values given before and after the hyphen or “to” as the respective lower limit value and upper limit value. In the present Description, the terms “film”, “sheet”, “plate”, and so forth are not distinguished from each other based simply on differences in the terms themselves. For example, “plate” is a concept that also includes members that could generally be referred to with “sheet” or “film”.

### [Method for Forming a Cured Film]

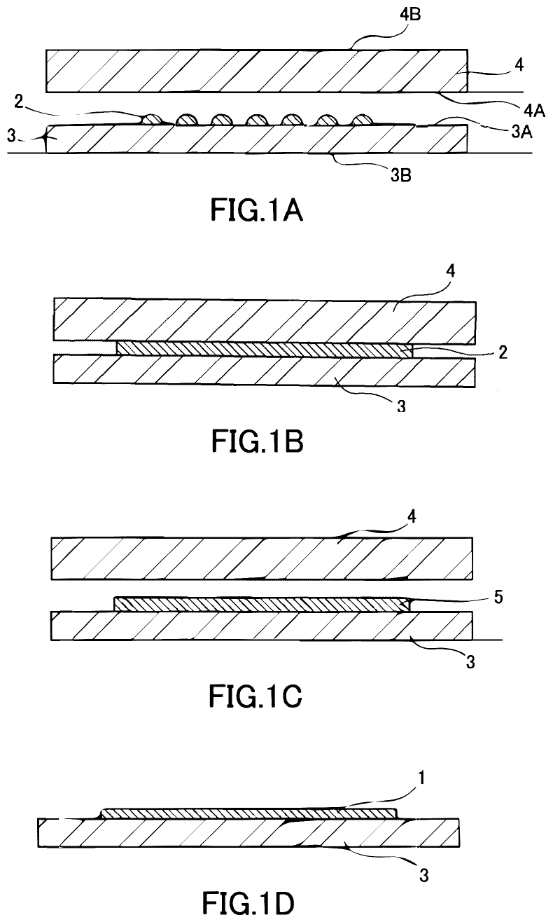

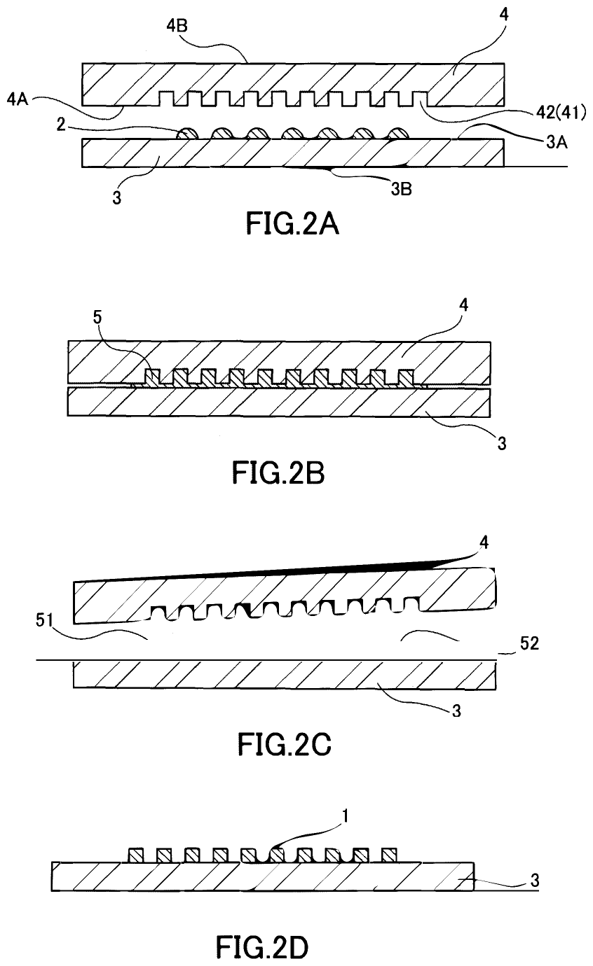

The method for forming a cured film according to the present embodiment includes a step of supplying a curable resin 2 to a substrate 3 (refer to FIG. 1A and FIG. 2A), a step of curing the curable resin 2 (refer to FIG. 1B, FIG. 1C, FIG. 2B, and FIG. 2C), and a step of forming a cured film 1 (refer to FIG. 1D and FIG. 2D).

The curable resin 2 in the present embodiment contains a polymerizable compound that has in the molecule an organic component and an inorganic component. The inorganic component may contain SiO_{X} (X is equal to or greater than 1), and the polymerizable compound may have a siloxane bond for the inorganic component and may have at least one polymerizable functional group.

Of the oxygen atoms bonded to the silicon atoms in this polymerizable compound, the proportion of oxygen atoms bonded to a single silicon atom in the polymerizable compound contained in the curable resin 2 in the present embodiment should be not more than 10 mol %. A single species, or a combination of a plurality of species, of a polymer, oligomer, and so forth for which constituent units are tetrafunctional silane, trifunctional silane, difunctional silane, and monofunctional silane can be used as the polymerizable compound.

In the present embodiment, the use is preferred, in conformity to the properties desired for the curable resin 2, of a polymerizable compound for which the constituent units are mainly trifunctional silane and difunctional silane.

Of the oxygen atoms bonded to the silicon atoms in this polymerizable compound, the proportion of oxygen atoms bonded to a single silicon atom in the polymerizable compound in the present embodiment should be not more than 10 mol % and is preferably not more than 7 mol % and particularly preferably not more than 5 mol %.

An oxygen atom bonded to a single silicon atom denotes an oxygen atom in which one of the two bonds of the oxygen atom is bonded to silicon and is not an oxygen atom in which both of the two bonds of the oxygen atom are bonded to a silicon atom. As long as the bonding is to other than silicon, the other bond for this oxygen atom is not particularly limited; however, bonding to hydrogen or a C₁₋₄ alkyl group is particularly preferred.

The timewise stability of the curable resin can be improved and viscosity increases during storage can be suppressed in the present embodiment by having the proportion of oxygen atoms bonded to a single silicon atom as described above, i.e., the proportion in which there is bonded a highly reactive functional group having a high reactivity for the silicon atom, such as the hydroxyl group (—OH) or alkoxy group (—OR, R is a C₁₋₄ alkyl group), be in the indicated range. For this same reason, reaction with the surface of the flat mold described below can also be suppressed and as a consequence the effect of an excellent releasability from the flat mold is achieved.

It is hypothesized that the reason that these high-reactivity functional groups are present in a certain proportion in the polymerizable compound is that they are unreacted oxygen atoms remaining in the process for producing the polymerizable compound. When the high-reactivity functional group is an alkoxy group (—OR, R is a C₁₋₄ alkyl group), the reason that such an unreacted oxygen atom remains present is thought to be that hydrolysis of the alkoxy group in the starting material did not progress; in the case of the hydroxyl group (—OH), it is thought that the polymerization reaction has not progressed completely due to steric hindrance and so forth.

The proportion of oxygen atoms bonded to a single silicon atom indicates in the present embodiment the number of oxygen atoms bonded to a single silicon atom using 100 for the number of oxygen atoms bonded to silicon atoms in the polymerizable compound. With regard to the method for measuring this proportion, it can be calculated by analysis of the spectrum provided by ²⁹Si-NMR.

Specifically, when NMR analysis is performed on a polymerizable compound containing a siloxane structure for which the constituent unit is trifunctional silane, four peaks are observed for: a component in which none of the three oxygen atoms bonded to a silicon atom are bonded to another silicon atom; a component in which one of the three oxygen atoms bonded to a silicon atom is bonded to another silicon atom; a component in which two of the three oxygen atoms bonded to a silicon atom are bonded to another silicon atom; and a component in which all of the three oxygen atoms bonded to a silicon atom are bonded to another silicon atom.

Using T⁰ to T³ for the integration values of these four peaks, that is, the ratios of their respective areas, the aforementioned proportion (mol %) of oxygen atoms bonded to a single silicon atom can then be calculated using the following formula (2).

$$\begin{matrix}[ Math . 2 ] & \\ \frac{{T}^{0} \times 3 + {T}^{1} \times 2 + {T}^{2} \times 1 + {T}^{3} \times 0}{( {T}^{0} + {T}^{1} + {T}^{2} + {T}^{3} ) \times 3} \times 100 & ( 2 )\end{matrix}$$

When the polymerizable compound contains a siloxane structure for which the constituent unit is difunctional silane, three peaks are observed for: a component in which none of the two oxygen atoms bonded to a silicon atom are bonded to another silicon atom; a component in which one of the two oxygen atoms bonded to a silicon atom is bonded to another silicon atom; and a component in which both of the two oxygen atoms bonded to a silicon atom are bonded to another silicon atom.

Using D⁰ to D² for the integration values of these three peaks, that is, the ratios of their respective areas, the aforementioned proportion (mol %) of oxygen atoms bonded to a single silicon atom can then be calculated using the following formula (3).

$$\begin{matrix}[ Math . 3 ] & \\ \frac{{D}^{0} \times 2 + {D}^{1} \times 1 + {D}^{2} \times 0}{( {D}^{0} + {D}^{1} + {D}^{2} ) \times 2} \times 100 & ( 3 )\end{matrix}$$

When the polymerizable compound contains a siloxane structure for which the constituent unit is tetrafunctional silane, five peaks are observed for: a component in which none of the four oxygen atoms bonded to a silicon atom are bonded to another silicon atom; a component in which one of the four oxygen atoms bonded to a silicon atom is bonded to another silicon atom; a component in which two of the four oxygen atoms bonded to a silicon atom are bonded to another silicon atom; a component in which three of the four oxygen atoms bonded to a silicon atom are bonded to another silicon atom; and a component in which all of the four oxygen atoms bonded to a silicon atom are bonded to another silicon atom.

Using Q⁰ to Q⁴ for the integration values of these five peaks, that is, the ratios of their respective areas, the aforementioned proportion (mol %) of oxygen atoms bonded to a single silicon atom can then be calculated using the following formula (4).

$$\begin{matrix}[ Math . 4 ] & \\ \frac{{Q}^{0} \times 4 + {Q}^{1} \times 3 + {Q}^{2} \times 2 + {Q}^{3} \times 1 + {Q}^{4} \times 0}{( {Q}^{0} + {Q}^{1} + {Q}^{2} + {Q}^{3} + {Q}^{4} ) \times 4} \times 100 & ( 4 )\end{matrix}$$

For example, when the curable resin 2 contains a polymerizable compound for which there are two species of constituent units in the form of trifunctional silane and difunctional silane, the proportion (mol %) of oxygen atoms bonded to a single silicon atom can be calculated from the following formula (5).

$$\begin{matrix}[ Math . 5 ] & \\ \frac{( {T}^{0} \times 3 + {T}^{1} \times 2 + {T}^{2} \times 1 + {T}^{3} \times 0 ) + ( {D}^{0} \times 2 + {D}^{1} \times 1 + {D}^{2} \times 0 )}{( {T}^{0} + {T}^{1} + {T}^{2} + {T}^{3} ) \times 3 + ( {D}^{0} + {D}^{1} + {D}^{2} ) \times 2} \times 100 & ( 5 )\end{matrix}$$

The weight-average molecular weight (Mw) of the polymerizable compound should be in the range from 500 to 100,000 and is preferably in the range from 600 to 50,000 and particularly preferably is in the range from 700 to 20,000.

This weight-average molecular weight (Mw) is the molecular weight as polystyrene provided by measurement by gel permeation chromatography (GPC), and is the value measured using the following conditions after pressure filtration using a membrane filter having a filter pore diameter of 0.2 μm.

### (Conditions)

instrument: Water 2695
sample size: approximately 10 mg sample per 3 mL solvent
injection amount: 5 μL
guard column: LF-G (Shodex)·
column: 3×GPC LF-804 (Shodex)·
column temperature: 40° C.
mobile phase: tetrahydrofuran
flow rate: 1.0 mL/min
detector: differential refractometer (Water 2414)·
molecular weight calibration: as polystyrene

This polymerizable compound has a polymerizable functional group that constitutes at least a portion of the organic component. The polymerizable functional group is a functional group that can undergo a polymerization reaction and is not particularly limited as long as a polymerization reaction can proceed upon external excitation. Use can be made of, for example, an acryloyl group, methacryloyl group, acryloyloxy group, methacryloyloxy group, epoxy group, oxetane group, vinyl ether group, and so forth, for which a polymerization reaction proceeds under the action of, for example, light irradiation, heat, the heat associated with light irradiation, a photoacid generator, and so forth. Such a polymerizable functional group has a good stability during synthesis and storage and has a good reactivity during curing, and the starting materials therefor are easily acquired.

The acryloyl group and methacryloyl group are particularly preferred in the present embodiment due to the breadth of the curing rates and the breadth of property selection.

When the polymerizable group directly bonded to a silicon atom in the polymerizable compound is bulky, the reactivity may be altered due to steric hindrance and there may be effects on, for example, the curability. Considering this point, the molecular weight of polymerizable groups directly bonded to a silicon atom should be in the range of 20 to 500 and is preferably in the range of 25 to 400. In the present embodiment, the polymerizable group refers to a group that contains a polymerizable functional group. The structures given below are preferred examples of this polymerizable group.

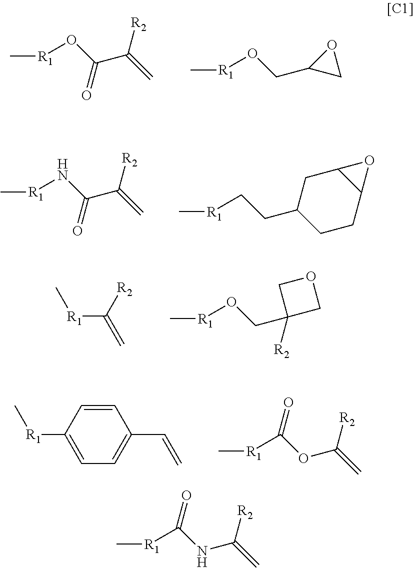

R¹ represents “a substituted or unsubstituted alkyl chain having 1 to 10 carbons” and R² represents “a substituted or unsubstituted alkyl chain having 1 to 3 carbons, or a hydrogen atom”. Both R¹ and R² may be straight chain or branched.

At least one polymerizable functional group as described above should be bonded in a constituent unit of the polymerizable compound, but there is no limitation to this and a polymerizable compound in which two or more are bonded may be used.

The following are examples of functional group-bearing constituent units of the polymerizable compound in the present embodiment.

The trifunctional constituent unit can be exemplified by 3-acryloxypropyltrimethoxysilane, 3-acryloxypropyltriethoxysilane, 3-methacryloxypropyltrimethoxysilane, 3-methacryloxypropyltriethoxysilane, vinyltrimethoxysilane, vinyltriethoxysilane, allyltrimethoxysilane, allyltriethoxysilane, styryltrimethoxysilane, styryltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, 3-ethyl-3-[3′-(trimethoxysilyl)propyl]methyloxetane, and 3-ethyl-3-[3′-(triethoxysilyl)propyl]methyloxetane, among which the use of the following is preferred: 3-acryloxypropyltrimethoxysilane, 3-acryloxypropyltriethoxysilane, 3-methacryloxypropyltrimethoxysilane, 3-methacryloxypropyltrimethoxysilane, 3-methacryloxypropyltriethoxysilane, vinyltrimethoxysilane, vinyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, 3-ethyl-3-[3′-(trimethoxysilyl)propyl]methyloxetane, and 3-ethyl-3-[3′-(triethoxysilyl)propyl]methyloxetane.

The difunctional constituent unit can be exemplified by 3-acryloxypropyl(methyl)dimethoxysilane, 3-acryloxypropyl(methyl)diethoxysilane, 3-methacryloxypropyl(methyl)dimethoxysilane, 3-methacryloxypropyl(methyl)diethoxysilane, vinyl(methyl)dimethoxysilane, vinyl(methyl)diethoxysilane, allyl(methyl)dimethoxysilane, allyl(methyl)diethoxysilane, styryl(methyl)dimethoxysilane, styryl(methyl)diethoxysilane, 3-glycidoxypropylmethyldiethoxysilane, 3-glycidoxypropylmethyldimethoxysilane, 2-(3,4-epoxycyclohexyl)ethyl(methyl)dimethoxysilane, 2-(3,4-epoxycyclohexyl)ethyl(methyl)diethoxysilane, 3-ethyl-3-[3′-(methyldimethoxysilyl)propyl]methyloxetane, 3-ethyl-3-[3′-(methyldiethoxysilyl)propyl]methyloxetane, dimethoxymethylvinylsilane, and diethoxymethylvinylsilane. Among these, the use of the following, for example, is preferred: 3-acryloxypropyl(methyl)dimethoxysilane, 3-acryloxypropyl(methyl)diethoxysilane, 3-methacryloxypropyl(methyl)dimethoxysilane, 3-methacryloxypropyl(methyl)diethoxysilane, vinyl(methyl)dimethoxysilane, vinyl(methyl)diethoxysilane, 3-glycidoxypropylmethyldiethoxysilane, 3-glycidoxypropylmethyldimethoxysilane, 2-(3,4-epoxycyclohexyl)ethyl(methyl)dimethoxysilane, 2-(3,4-epoxycyclohexyl)ethyl(methyl)diethoxysilane, 3-ethyl-3-[3′-(methyldimethoxysilyl)propyl]methyloxetane, and 3-ethyl-3-[3′-(methyldiethoxysilyl)propyl]methyloxetane.

The combination of a polymerizable group-free constituent unit with a polymerizable group-bearing constituent unit can also be used. Trifunctional constituent units that are examples of polymerizable group-free constituent units are trimethoxy(methyl)silane, triethoxy(methyl)silane, methyltripropoxysilane, tributoxy(methyl)silane, methyltriphenoxysilane, ethyltrimethoxysilane, triethoxy(ethyl)silane, ethyltripropoxysilane, tributoxy(ethyl)silane, ethyltriphenoxysilane, trimethoxy(propyl)silane, triethoxy(propyl)silane, tripropoxy(propyl)silane, tributoxy(propyl)silane, triphenoxy(propyl)silane, butyltrimethoxysilane, butyltriethoxysilane, butyltripropoxysilane, tributoxy(butyl)silane, butyltriphenoxysilane, trimethoxy(phenyl)silane, triethoxy(phenyl)silane, phenyltripropoxysilane, tributoxy(phenyl)silane, triphenoxy(phenyl)silane, cyclohexyltrimethoxysilane, cyclohexyltriethoxysilane, cyclohexyltripropoxysilane, and cyclohexyltributoxysilane, cyclohexyltriphenoxysilane. Among these, the use of the following, for example, is preferred: trimethoxy(methyl)silane, triethoxy(methyl)silane, ethyltrimethoxysilane, triethoxy(ethyl)silane, trimethoxy(phenyl)silane, triethoxy(phenyl)silane, cyclohexyltrimethoxysilane, and cyclohexyltriethoxysilane.

The following, for example, can preferably be used as a difunctional constituent: dimethoxydimethylsilane, diethoxydimethylsilane, methylphenyldimethoxysilane, methylphenyldiethoxysilane, cyclohexyl(dimethoxy)methylsilane, cyclohexyldiethoxymethylsilane, dimethoxydiphenylsilane, diethoxydiphenylsilane, dimethoxymethylvinylsilane, and diethoxymethylvinylsilane.

There are no particular limitations in the present embodiment on the structure of the polymerizable compound. However, it is preferably a polymerizable compound having a spherical structure, infra, or a polyhedral siloxane oligomer having an incompletely condensed skeleton, because this enables the preparation of a curable resin 2 that has a sufficiently low viscosity even substantially without containing solvent. In particular, a polymerizable compound having a spherical structure is preferred from the standpoints of, inter alia, the thermal stability and processing uniformity.

The spherical structure denotes a structure in which the polymerizable functional group extends in the outward direction from a center of a polymerization part having a high degree of polymerization. For example, in the case of a polymerizable compound having a spherical structure, for example, a dendrimer, the viscosity of the curable resin 2 can be adequately reduced by bringing the proportion of oxygen atoms bonded to a single silicon atom, of the oxygen atoms bonded to the silicon atoms contained in the polymerizable compound, to not more than 10 mol %, and by the addition of a small amount of solvent or a low-viscosity material.

The polymerizable compound having a spherical structure can be exemplified by such compounds for which trifunctional silane is a constituent unit. Preferred thereamong are such compounds in which the constituent unit is only trifunctional silane. Such a polymerizable compound having a spherical structure can be exemplified by a single species, or a mixture of two or more species, of 6-mer to 36-mer (molecular weight from 1,000 to 6,300) of a polymerizable functional group-bearing trifunctional silane. The molecular weight of the polymerizable compound having a spherical structure may be in the range from 2,000 to 6,000 and preferably may be in the range from 2,000 to 3,000.

A siloxane composed of trifunctional silane generally has a structure in which the polymerizable functional groups extend outward from a center of a siloxane polymerization part having a high degree of polymerization for siloxane composed of the SiO_{3/2} unit. In such a polymerizable compound having a spherical structure, the siloxane degree of polymerization in the siloxane polymerization part can be brought to higher than 90% and particularly at least 95% and more particularly at least 97%, and as a consequence the proportion of oxygen atoms bonded to a single silicon atom, of the oxygen atoms bonded to the silicon atoms contained in the polymerizable compound, will be brought to 10 mol % or less.

The reason for this is hypothesized to be as follows. That is, when the hydrolysis reaction of trifunctional silane is carried out under basic conditions, a nucleophilic reaction by OH″ on the Si atom is produced. The hydrolysis reaction rate is increased because the steric hindrance on the Si atom is reduced by the hydrolysis reaction of one hydrolyzable group (alkoxy group), and —Si(OH)₃, in which all three of the hydrolyzable groups (alkoxy groups) are hydrolyzed, is produced. Because all of the OH groups in —Si(OH)₃ are condensable, a three-dimensional siloxane structure having a high density and high degree of polymerization is formed.

In specific terms, the spherical structure given by the following formula is exhibited. The following formula is a schematic diagram that shows a polymerizable compound having a spherical structure, which is composed of an octamer of a trifunctional silane respectively having the acryloxypropyl group and 3-methacryloxypropyl group as the polymerizable group.

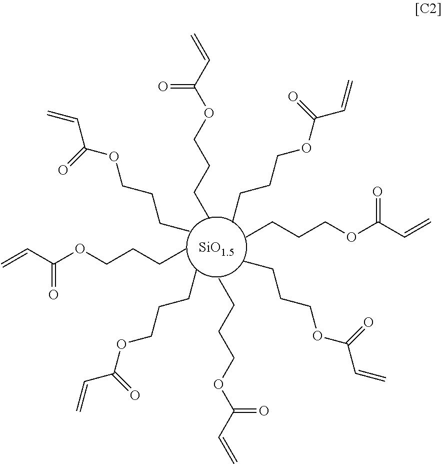

The Sio_{1.5} in the formula represents a siloxane polymerization part composed of the SiO_{3/2} unit.

In the present disclosure, this polymerizable compound having a spherical structure may be such a compound that does not having an oxygen atom, nitrogen atom, phosphorus atom, or sulfur atom in the linking group between the polymerizable functional group and the siloxane polymerization part that constitutes the main skeleton of the spherical structure, and may be such a compound that does not have the oxygen atom, nitrogen atom, phosphorus atom, or sulfur atom between the polymerizable functional group and the silicon atom (for example, the silicon atom in the SiO_{3/2} unit) in the siloxane polymerization part that constitutes the main skeleton of the spherical structure.

The linking group between the polymerizable functional group and the silicon atoms in the siloxane polymerization part can be exemplified by a divalent hydrocarbon group that lacks the oxygen atom, nitrogen atom, phosphorus atom, and sulfur atom, and is preferably a straight-chain alkylene group and is more preferably-(CH₂)ₙ-(n is an integer from 1 to 9).

The polymerizable compound having a spherical structure can be obtained by subjecting a hydrolyzable silane composition containing at least hydrolyzable silane to a hydrolysis and condensation reaction under basic conditions.

In specific terms, this can be carried out by introducing a solvent and silane functioning as the starting material into a reactor, adding a basic substance that is the catalyst, and carrying out the dropwise addition of water while stirring. The basic substance can be exemplified by sodium hydroxide, potassium hydroxide, lithium hydroxide, potassium carbonate (K₂CO₃), sodium carbonate, and ammonia, and the pH is brought to 8 to 13 and the reaction is generally carried out at from room temperature to 100° C.

The silane making up the starting material should be at least one species selected from any of tetrafunctional hydrolyzable silane, trifunctional hydrolyzable silane, difunctional hydrolyzable silane, and monofunctional hydrolyzable silane, but the use is preferred of tetrafunctional hydrolyzable silane or trifunctional hydrolyzable silane and in particular trifunctional hydrolyzable silane. In addition, only a single species of hydrolyzable silane may be used or two or more species may be used combination.

By using a basic catalyst for the catalyst in the synthesis step as indicated in the preceding, the polymerizable compound yielded by the hydrolysis and condensation reaction will assume a high degree of condensation. This makes it possible to readily obtain a polymerizable compound having a spherical structure, in which the proportion of oxygen atoms bonded to a single silicon atom, of the oxygen atoms bonded to silicon atoms, is reduced and in particular is reduced to 10 mol % or less.

The polymerizable compound in the present embodiment may be a polyhedral siloxane oligomer having an incompletely condensed skeleton. Such a polymerizable compound has a regular structure, and due to this the proportion of oxygen atoms bonded to a single silicon atom, of the oxygen atoms bonded to the silicon atoms contained in the polymerizable compound, will become 10 mol % or less. The viscosity of the curable resin can also be brought to a satisfactorily low level.

Polyhedral siloxane oligomer having a polymerizable functional group bonded therein and having an incompletely condensed skeleton, can be exemplified by incompletely condensed types of polyhedral siloxane oligomer having an incompletely condensed skeleton in which one vertex, one edge, or one surface is absent. The structures given by the following formulas are particularly preferred for the polyhedral siloxane oligomer having a polymerizable functional group bonded therein and having an incompletely condensed skeleton.

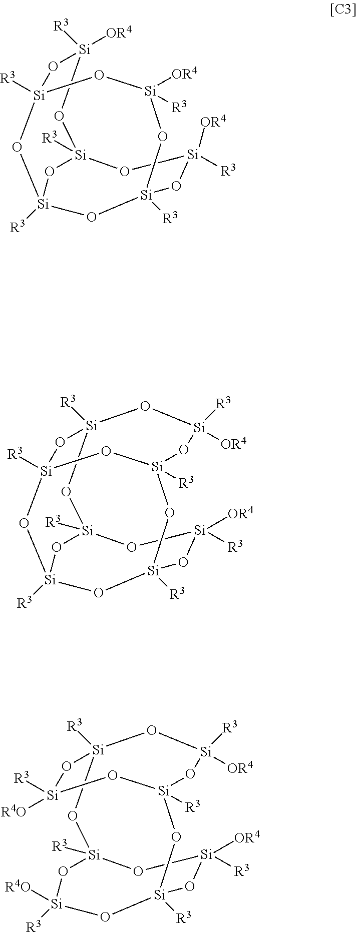

In these formulas, R³ is a monovalent hydrocarbon group and R⁴ is —Si-polymerizable group bonded to an oxygen atom in the formula, or is a hydrogen atom or metal ion, e.g., Na or Li, or is a tetraalkylammonium ion (with, e.g., methyl, ethyl, propyl, or butyl for the alkyl group). R³ is a monovalent hydrocarbon group and is preferably a C₁₋₅ alkyl group or the phenyl group and can be specifically exemplified by the ethyl group, butyl group, and phenyl group.

The instant polymerizable compound can be obtained by reacting a polymerizable functional group-containing compound with a polyhedral siloxane oligomer having an incompletely condensed skeleton and having a silicon atom-bonded hydrogen atom, hydroxy group, or organic group other than a polymerizable functional group.

A hydrogen atom, hydroxy group, or organic group other than a polymerizable functional group is bonded to a silicon atom located at a vertex in the starting polyhedral siloxane oligomer having an incompletely condensed skeleton. This organic group other than a polymerizable functional group can be exemplified by alkoxy groups, alkyl groups, and the phenyl group.

The reaction between this starting material and the polymerizable functional group-containing compound can be exemplified by heretofore known reactions. For example, the reaction may be an addition reaction between a hydrogen atom directly bonded to silicon and a polymerizable functional group-containing compound having an unsaturated double bond, or may be a reaction between a hydroxy group (OH group) or alkoxy group (OR group) directly bonded to silicon and a polymerizable functional group-containing compound that can form a siloxane bond.

The curable resin 2 in the present embodiment should contain a polymerization initiator. The polymerization initiator can be exemplified by photopolymerization initiators and thermal polymerization initiators, with photopolymerization initiators being preferred.

The photopolymerization initiator is a substance that generates, due to photoexcitation, a reactive species that induces the polymerization reaction of the polymerizable compound. Specific examples are photoradical generators, which generate radicals under photoexcitation, and photoacid generators, which generate protons under photoexcitation. Photoradical generators are polymerization initiators that produce radicals under the action of light (infrared, visible, ultraviolet, far ultraviolet, X-ray; charged particle beams, e.g., electron beams; and radiation), and are mainly used when the polymerizable compound is a radical polymerizable compound. Photoacid generators, on the other hand, are polymerization initiators that produce acid (protons) under the action of light, and are mainly used when the polymerizable compound is a cationic polymerizable compound.

The photoradical generator can be exemplified by 2,4,6-trimethyldiphenylphosphine oxide, 2,2-dimethoxy-2-phenylacetophenone, 2-methyl-1-[4-(methylthio)phenyl]-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 2-hydroxy-2-methyl-1-phenylpropan-1-one, and 2-hydroxy-2-methyl-1-phenylpropan-1-one, but there is no limitation to these. A single species of these photoradical generators can be used by itself, or a combination of two or more species may be used.

The photoacid generator can be exemplified by onium salt compounds, sulfone compounds, sulfonate ester compounds, sulfonimide compounds, and diazomethane compounds, but there is no limitation to these.

The thermal polymerization initiator is a compound that generates the aforementioned polymerization factors (radical, cation, and so forth) under the action of heat. The thermal polymerization initiator can be specifically exemplified by thermal radical generators, which generate a radical under the action of heat, and thermal acid generators, which generate a proton (H+) under the action of heat. A thermal radical generator is used mainly when the polymerizable compound is a radical polymerizable compound. A thermal acid generator, on the other hand, is used mainly when the polymerizable compound is a cationic polymerizable compound.

The thermal acid generators can be exemplified by organoperoxides and azo compounds. The organoperoxides can be exemplified by peroxyesters, e.g., t-hexylperoxy isopropyl monocarbonate, t-hexylperoxy 2-ethylhexanoate, t-butylperoxy 3,5,5-trimethylhexanoate, and t-butylperoxy isopropyl carbonate; peroxyketals, e.g., 1,1-bis(t-hexylperoxy)-3,3,5-trimethylcyclohexane; and diacyl peroxides, e.g., lauroyl peroxide, but there is no limitation to these. The azo compounds can be exemplified by azonitriles such as 2,2′-azobisisobutyronitrile, 2,2′-azobis(2-methylbutyronitrile), and 1,1′-azobis(cyclohexane-1-carbonitrile), but there is no limitation to these.

The thermal acid generator can be exemplified by known iodonium salts, sulfonium salts, phosphonium salts, and ferrocenes. Specific examples are diphenyliodonium hexafluoroantimonate, diphenyliodonium hexafluorophosphate, diphenyliodonium hexafluoroborate, triphenylsulfonium hexafluoroantimonate, triphenylsulfonium hexafluorophosphate, and triphenylsulfonium hexafluoroborate, but there is no limitation to these.

The content of the polymerization initiator in the curable resin 2 is not particularly limited, but, relative to the aforementioned polymerizable compound, can be in the range of 0.5 mass % to 20 mass % or can be in the range of 1 mass % to 10 mass %.

The curable resin 2 in the present embodiment may substantially not contain a solvent. The substantial absence of solvent makes it possible to suppress the curing defects and deterioration in flatness that are caused by migration of solvent to the surface during curing. This “substantially not contain a solvent” means that solvent—other than solvent that ends up being unintentionally contained, for example, impurities—is not contained. That is, for example, the solvent content in the curable resin 2, with reference to the total curable resin 2, is preferably not more than 0.01 mass % and is more preferably not more than 0.001 mass %. The solvent denotes those solvents used in, for example, common or general resin compositions or photoresists. That is, the solvent species is not particularly limited as long as it dissolves and uniformly disperses the curable resin 2 and does not react with the curable resin 2.

The curable resin 2 may contain a reactive crosslinking agent. This reactive crosslinking agent has a polymerizable functional group and can be exemplified by reactive crosslinking agents that have two or more polymerizable functional groups. The polymerizable functional group can be exemplified by ethylenically unsaturated bond-containing groups, the epoxy group, and so forth, and is advantageously an ethylenically unsaturated bond-containing group. The ethylenically unsaturated bond-containing group can be exemplified by the (meth)acrylic group, vinyl group, and so forth, with the (meth)acrylic group being more preferred and the acrylic group being even more preferred. In addition, the (meth)acrylic group is preferably the (meth)acryloyloxy group. Two or more species of polymerizable group may be contained in a single molecule, or two or more of the same species of polymerizable group may be contained.

Photopolymerizable monomer containing two polymerizable functional groups (difunctional monomer) can be exemplified by trimethylolpropane di(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, and bis(hydroxymethyl)tricyclodecane di(meth)acrylate. Commercially available difunctional monomers can be exemplified by Light Acrylate 3EG-A, 4EG-A, 9EG-A, NP-A, DCP-A, BP-4EAL, and BP-4PA (all manufactured by Kyoeisha Chemical Co., Ltd.). In addition, polyfunctional monomers having a siloxane structure are preferred from a compatibility standpoint.

There are no particular limitations on the content of the reactive crosslinking agent, and it can be present in the curable resin 2 in the range from 0 mass % to 99 mass %, preferably in the range from 5 mass % to 80 mass %, and particularly preferably in the range from 49 mass % to 79 mass %.

The curable resin 2 may contain compositions other that the polymerizable compound, polymerization initiator, and reactive crosslinking agent that have been described in the preceding. These other components can be exemplified by other components such as, as necessary, a surfactant, release agent, silane coupling agent, photosensitizer, antioxidant, organometal coupling agent, polymerization inhibitor, ultraviolet absorber, photostabilizer, ageing inhibitor, plasticizer, adhesion promoter, photobase generator, colorant, elastomer particle, photoacid multiplier, basic compound, other flow regulator, antifoam, and dispersing agent. The content of these other components is not particularly limited, but is preferably not more than 5 mass % in the curable resin 2 and particularly preferably is not more than 3 mass %.

The viscosity of the curable resin 2 should be not more than 20 cPs and should preferably be not more than 10 cPs and more preferably should be not more than 7 cPs. On the other hand, while the lower limit for the viscosity is not particularly limited, it can be at least 1 cPs and is preferably at least 1.5 cPs. Since the curable resin 2 has a very low viscosity, it can be coated on a relief structure with good fillability while suppressing the generation of bubbles. In addition, coating by an inkjet technique is made possible at such a low viscosity. The viscosity of the curable resin 2 is the value at 25° C. and 1000 (1/s) measured using an AR-G2 from TA Instruments and operating in a 25° C. and 40% RH measurement environment, dripping the curable resin 2 onto the disk plate, and varying a 40 mm-diameter standard steel cone over a shear rate of 10 to 1000 (1/s).

The curable resin 2 preferably exhibits a contact angle, versus the surface of a standard resist, of not more than 20° and more preferably not more than 15°. This contact angle can be specifically measured, operating in a normal pressure atmosphere at a temperature of 25° C. and a humidity of 33%, by dripping the curable resin 2 onto the surface of a standard resist layer and carrying out measurement after 5 seconds using a contact angle meter (DM-501 Automatic Contact Angle Meter from Kyowa Interface Science Co., Ltd.). The standard resist layer, for example, may be formed using an acrylic-styrene copolymer (organic resist resin) as the base resin.

When a contact angle versus a standard resist layer is exhibited, for example, in the case of use as an inversion layer material in an inversion process, the wettability versus the core material pattern formed from a resist composition then becomes excellent and as a consequence coating with a better fillability can be carried out. When curable resin 2 exhibits the aforementioned contact angle versus a standard resist, an excellent wettability is exhibited even when the composition of the organic resist material actually used as the core material pattern is different from the composition of the standard resist.

The surface free energy of the curable resin 2 is preferably from 20 mJ/m² to 70 mJ/m² and is particularly preferably from 25 mJ/m² to 50 mJ/m². Such a range is preferred because, for example, miscibility with the core material pattern composed of organic resist material can be suppressed and a satisfactory wetting and spreading onto the core material pattern occurs.

In the method for forming a cured film according to the present embodiment, there are no particular limitations on the substrate 3 to which the curable resin 2 is supplied, and it can be exemplified by transparent substrates such as glass substrates, e.g., alkali-free glass substrates such as quartz glass substrates, soda glass substrates, fluorite substrates, calcium fluoride substrates, magnesium fluoride substrates, barium borosilicate glasses, alminoborosilicate glasses, and aluminosilicate glasses, and resin substrates such as polycarbonate substrates, polypropylene substrates, polyethylene substrates, polymethyl methacrylate substrates, and polyethylene terephthalate substrates; and by semiconductor substrates such as silicon substrates, GaAs substrates, InP substrates, GaN substrates, GaP substrates, and SiC substrates; metal base substrates such as stainless steel substrates, aluminum substrates, copper substrates, and iron substrates; and metal vapor-deposited substrates as provided by the vapor deposition on the surface of, e.g., a glass substrate, of a metal such as gold, silver, copper, ITO, and chromium. The substrate may be, for example, a layered substrate as provided by stacking two or more substrates selected without limitation from those listed in the preceding. In the present embodiment, “transparent” indicates that the transmittance of light with a wavelength of 300 nm to 450 nm is at least 70% and preferably is at least 90%.

The substrate 3 has a first surface 3A and a second surface 3B located on an opposite side therefrom, and a curable resin 2 is supplied to the first surface 3A of the substrate 3 (refer to FIG. 1A and FIG. 2A). There are no particular limitations on the method for supplying the curable resin 2 to the first surface 3A of the substrate 3, and, for example, the curable resin 2 may be discretely supplied to the first surface 3A of the substrate 3 by an inkjet method, or a method may be used in which the curable resin 2 is coated on the first surface 3A of the substrate 3 using a coating device such as a spin coater or a spray coater.

A mold 4 is brought into proximity to the curable resin 2 supplied to the first surface 3A of the substrate 3 to deploy the curable resin 2 between the substrate 3 and the mold 4 and form a shape-receiving resin layer 5 (contact step, refer to FIG. 1B and FIG. 2B).

The mold 4 may be composed of, for example, a transparent substrate such as a glass substrate, e.g., a quartz glass substrate, soda glass substrate, fluorite substrate, calcium fluoride substrate, magnesium fluoride substrate, or acrylic glass; a resin substrate such as a polycarbonate substrate, polypropylene substrate, polyethylene substrate, or polyethylene terephthalate substrate; or a layered substrate as provided by stacking two or more substrates selected without limitation from those listed in the preceding.

The mold 4 may be a flat mold having a first surface 4A and a second surface 4B located on an opposite side therefrom, with the first surface 4A being a flat and smooth surface (refer to FIG. 1A), and a recess part 42—containing relief structure 41 may be formed in the first surface 4A (refer to FIG. 2A). The shape of the relief structure 41 formed in the first surface 4A of the mold 4 is not particularly limited and can be exemplified by space shapes, hole shapes, and so forth. The dimensions of the relief structure 41 are also not particularly limited and can be exemplified by a length in the short direction of the recess part 42 in the case of a space-shaped relief structure 41 of approximately 10 nm to 100 nm and a maximum diameter of the recess part 42 of approximately 10 nm to 100 nm in the case of a hole-shaped relief structure. The maximum diameter of a hole-shaped recess part 42, for example, is the diameter of the circle when the shape of the recess part 42 in plan view is a circular shape and is the length of the diagonal of the square in the case of a square shape. The dimensions of a plurality of recess parts 42 present in the relief structure 41 of the mold 4 may differ from each other, in which case the dimension of the minimum among the plurality of recess parts 42 (minimum dimension) may be equal to or less than 100 nm.

The shape-receiving resin layer 5 is hardened or cured (curing step) while the mold 4 is in contact with the shape-receiving resin layer 5 (curable resin 2). The method for curing the shape-receiving resin layer 5 may be selected as appropriate in correspondence to the curing mode for the curable resin 2 that constitutes the shape-receiving resin layer 5. For example, when the curable resin 2 is a photocuring type, the shape-receiving resin layer 5 (curable resin 2) may be exposed to light (for example, ultraviolet radiation, electron beam, and so forth) via the mold 4. If the curable resin 2 is a thermosetting type, heat may be applied to the shape-receiving resin layer 5 (curable resin 2). When the curable resin 2 is a thermoplastic type, the shape-receiving resin layer 5, which has been heated and softened, may be brought into contact with the mold 4 and the shape-receiving resin layer 5 may be hardened by cooling in this configuration.

The film thickness of the cured shape-receiving resin layer 5 is important from the standpoint of formation of the cured film 1 (refer to FIG. 1D and FIG. 2D). As described below, by executing an etching treatment on the cured shape-receiving resin layer 5 (curable resin 2), the organic component in the shape-receiving resin layer 5 (curable resin 2) is decomposed while the inorganic component contained as the main component of the siloxane polymerization part is retained and concentrated, thereby forming the cured film 1. Desorption of the inorganic component is produced by the etching treatment of the shape-receiving resin layer 5, at the same time that bonding within the inorganic component is produced. When the film thickness of the shape-receiving resin layer 5 is relatively thin, almost all of the inorganic component undergoes desorption and formation of the cured film 1 is then problematic. However, by having the film thickness of the shape-receiving resin layer 5 be relatively thick, the inorganic component bonded to other inorganic component undergoes concentration and a cured film 1 having a desired film thickness can be formed.

Accordingly, the film thickness of the cured shape-receiving resin layer 5 may be established as appropriate at a value that enables the formation of a cured film 1 having a desired film thickness. For example, a shape-receiving resin layer 5 having a prescribed film thickness T₀ may be formed by determining the amount of curable resin 2 to be supplied to the first surface 3A of the substrate 3 based on the following formula (1), which shows the relationship among the film thickness T₀ of the cured shape-receiving resin layer 5, the film thickness T of the cured film 1 to be formed, and the decomposition treatment time t for decomposition of the organic component.

$$\begin{matrix}[ Math . 6 ] & \\ T = {T}_{0} - {\int }_{0}^{t} {Ab}^{ct} dt - α t & ( 1 )\end{matrix}$$

In formula (1), Ab^{ct} represents “the decrement per unit time in the film thickness of the shape-receiving resin layer 5, which changes in accordance with the decomposition treatment time t, in the initial stage of the organic component decomposition treatment”; at represents “the decrement per unit time in the film thickness of the shape-receiving resin layer 5, which substantially does not change in accordance with the decomposition treatment time t”; A represents “the film thickness decrement in the shape-receiving resin layer 5 per unit time in the initial stage of the organic component decomposition treatment”; b and c are “coefficients that represent the exponential decrease in the film thickness of the shape-receiving resin layer 5”; and b>1 and c<0. When both coefficients b and c have large absolute values, a large value is assumed by the decrement per unit time in the film thickness of the shape-receiving resin layer 5, which changes in accordance with the decomposition treatment time t. The coefficients b and c each change with the conditions during decomposition of the organic component in the shape-receiving resin layer 5 and can each be established as appropriate in conformity with these conditions.

Formula (1) contains a component whereby the film thickness of the shape-receiving resin layer 5 varies as an exponential function and a component that varies as a linear function. This component that varies as an exponential function can be regarded as representing the state in which the inorganic component bonded with other inorganic component undergoes concentration and said inorganic component remains present with the elapse of the decomposition treatment time t. On the other hand, the component that varies as a linear function can be regarded as representing the state in which, due to physical etching, the film thickness of the shape-receiving resin layer 5 declines substantially in proportion to the decomposition treatment time t.

The “the initial stage of the organic component decomposition treatment” is determined by, for example, the type of organic component contained in the shape-receiving resin layer 5 (curable resin 2) and the conditions in the etching treatment carried out on the shape-receiving resin layer 5, and, for example, may be from the start of the shape-receiving resin layer 5 etching treatment to about 10 seconds to 300 seconds thereafter and is preferably from the start of the etching treatment to about 10 seconds to 60 seconds thereafter.

After separating the mold 4 from the cured shape-receiving resin layer 5 (release step, refer to FIG. 1C and FIG. 2C), the cured film 1 is formed (refer to FIG. 1D and FIG. 2D) by executing an etching treatment on the shape-receiving resin layer 5 (curable resin 2). The etching treatment executed on the shape-receiving resin layer 5 may be a dry etching treatment (plasma treatment), in which etching is carried out in a plasma discharge atmosphere in a vacuum chamber using oxygen gas, nitrogen gas, argon gas, chlorine gas, or a gas provided by mixing two or more of these, or may be a wet etching treatment (oxidation treatment), in which the shape-receiving resin layer 5 is brought into contact with an etching solution that exhibits an oxidizing capability, e.g., sulfuric acid or aqueous hydrogen peroxide. These etching treatments can decompose the organic component while causing bonding within the inorganic component and concentration thereof. As a result, a cured film 1 mainly containing inorganic component can be formed.

When formation of the cured film 1 on the first surface 3A of the substrate 3 will be carried out, a cured film formation region 31, where the cured film 1 will be formed, and a non-cured-film-formation region 32, where the cured film 1 will not be formed, may be established on the first surface 3A of the substrate 3, and the shape-receiving resin layer 5 may be formed by supplying the curable resin 2 to the cured film formation region 31 in an amount established based on formula (1) such that the film thickness T of the cured film 1 exceeds 0, and by supplying the curable resin 2 to the non-cured-film-formation region 32 in an amount established based on formula (1) such that the film thickness T of the cured film 1 is not greater than 0. For example, as shown in FIG. 2A to FIG. 2D, when formation of the shape-receiving resin layer 5 is performed using a mold 4 in which a recess part 42—containing relief structure 41 is formed, a protruding part 51 is formed in the shape-receiving resin layer 5 in correspondence to the recess part 42, and a recess part (residual film part) 52 is formed in the shape-receiving resin layer 5 in correspondence to the protruding part between adjacent recess parts 42. Due to this, a region where a protruding part 51 of the shape-receiving resin layer 5 is to be located is configured as a cured film formation region 31, and a region where a recess part (residual film part) 52 is to be located is configured as a non-cured-film-formation region 32. In addition, the shape-receiving resin layer 5 is formed by determining, based on formula (1), the height of the protruding part 51 of the shape-receiving resin layer 5 and the thickness of the recess part (residual film part) 52 of the shape-receiving resin layer 5 such that the protruding part 51 of the shape-receiving resin layer 5 remains present as the cured film 1 and the recess part (residual film part) 52 of the shape-receiving resin layer 5 is abolished. A patterned cured film 1 as shown in FIG. 2D can thereby be formed.

The thusly formed cured film 1 mainly contains inorganic component and more specifically mainly contains SiO_{X} (X is equal to or greater than 1). This “mainly contains” indicates that the cured film 1 may contain organic component, or, stated differently, it includes the idea that the content of the inorganic component in the cured film 1 is larger than the content of the inorganic component in the curable resin 2.

The film thickness T of the cured film 1 is thinner than the film thickness T₀ of the shape-receiving resin layer 5. The etching treatment for forming the cured film 1 has the purpose of decomposing the organic component in the shape-receiving resin layer 5 (curable resin 2) while also producing desorption of the inorganic component. Accordingly, shown in FIG. 2D (dimensions of the protrusion pattern) are then smaller than the dimensions (dimensions of the protrusion pattern) of the patterned shape-receiving resin layer 5 (refer to FIG. 2C). In other words, by forming the patterned cured film 1 using the mold 4 having the relief structure 41, it is possible to form the patterned cured film 1 having the protrusion pattern with the dimensions smaller than the minimum dimensions of the recess parts 42 of the relief structure 41 of the mold 4.

In the method for forming a cured film according to the present embodiment, at least one material layer constituted of a material different from the material constituting the substrate 3, may be disposed on the first surface 3A of the substrate 3 where the cured film 1 will be formed, and the cured film 1 may then be formed on this material layer. There are no particular limitations on this material layer, and it can be exemplified by hard mask layers composed of, e.g., chromium metal; semiconductor layers composed of a p-type semiconductor such as boron-doped silicon or a n-type semiconductor such as arsenic-doped silicon; and conductive film layers composed of, e.g., ITO.

### [Method for Manufacturing an Imprint Mold Substrate]

The method for manufacturing an imprint mold substrate according to the present embodiment is described in the following. The following method is provided as an example for the present embodiment: a method for manufacturing an imprint mold substrate 10 comprising a base 11 having a first surface 11A and a second surface 11B located on an opposite side from the first surface 11A; a first step structure 12 that protrudes from the first surface 11A of the base 11; a second step structure 13 that protrudes from an upper surface part 12A of the first step structure 12; a light-blocking film 14 that is located on the upper surface part 12A of the first step structure 12; and a cured film 1 functioning as a protective film 15 and located on the light-blocking film 14. However, there is no limitation to this method for manufacturing an imprint mold substrate 10 according to the indicated mode.

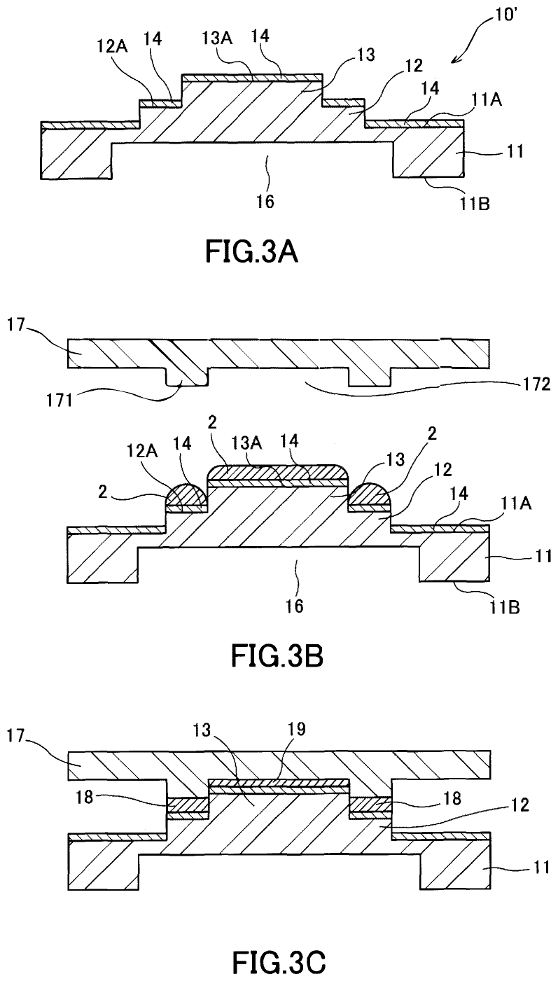

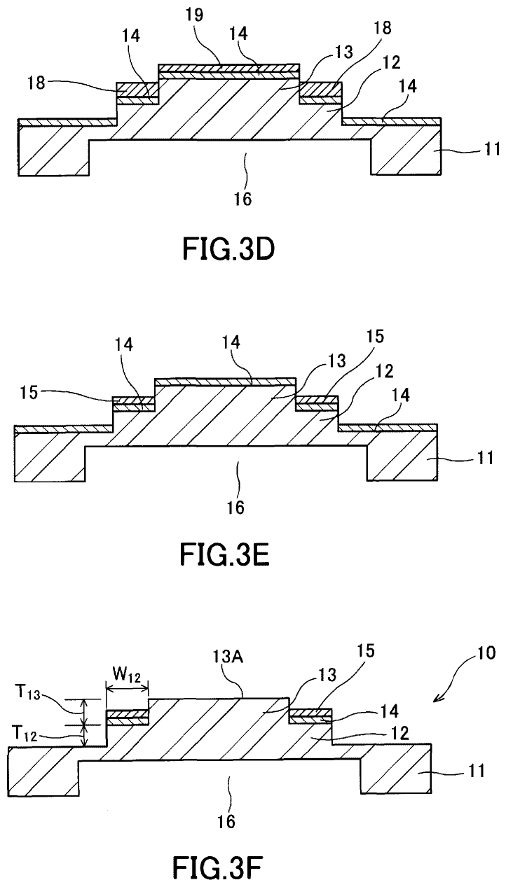

A multistep mold substrate 10′ is first prepared in the present embodiment (refer to FIG. 3A). The multistep mold substrate 10′ is provided with a base 11 having a first surface 11A and having a second surface 11B located on an opposite side from the first surface 11A; a first step structure 12 that protrudes from the first surface 11A of the base 11; a second step structure 13 that protrudes from an upper surface part 12A of the first step structure 12; and a light-blocking film 14 that is located on the first surface 11A of the base 11, the upper surface part 12A of the first step structure 12 and on an upper surface part 13A of the second step structure 13. There is formed in the second surface 11B of the base 11 a recess 16 having a size that can physically include the outer edge, in plan view, of the first step structure 12.

The base 11 may be a base as generally used for imprint mold substrates, and, for example, may be a transparent substrate such as a glass substrate, e.g., alkali-free glass substrates such as quartz glass substrates, soda glass substrates, fluorite substrates, calcium fluoride substrates, magnesium fluoride substrates, barium borosilicate glasses, alminoborosilicate glasses, and aluminosilicate glasses; a resin substrate such as polycarbonate substrates, polypropylene substrates, polyethylene substrates, polymethyl methacrylate substrates, and polyethylene terephthalate substrates; and layered substrates as provided by stacking two or more substrates selected without limitation from those listed in the preceding.

The shape of the base 11 in plan view is not particularly limited and can be exemplified by an approximately rectangular shape. The plan view shape of the base 11 is typically an approximately rectangular shape when the base 11 comprises a quartz glass substrate as generally used for photoimprint applications.

The size of the base 11 (size in plan view) is also not particularly limited, but, for example, the size of the base 11 is approximately 152 mm×152 mm when the base 11 comprises the aforementioned quartz glass substrate. In addition, the thickness of the base 11 can be established as appropriate in the range of, for example, approximately 300 μm to 10 mm, based on considerations of the strength, handling suitability, and so forth.

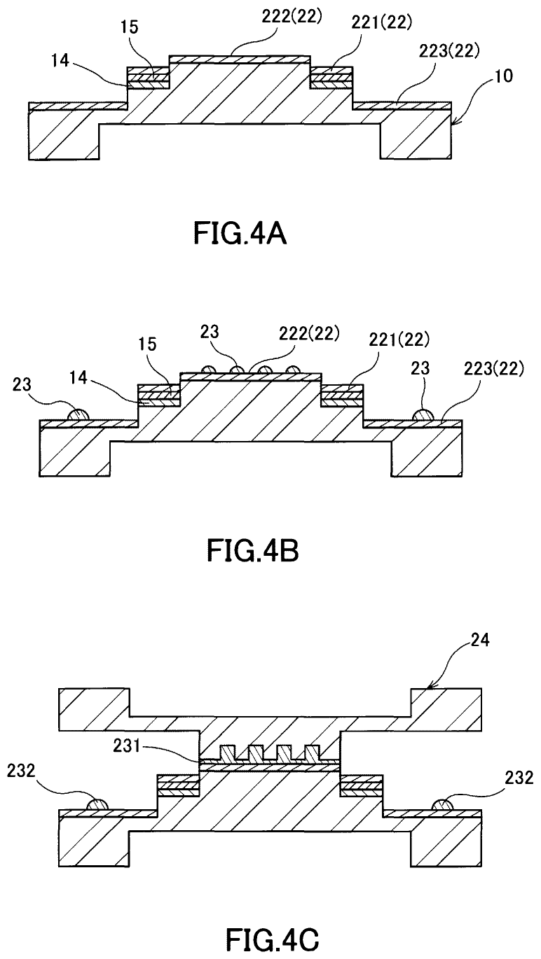

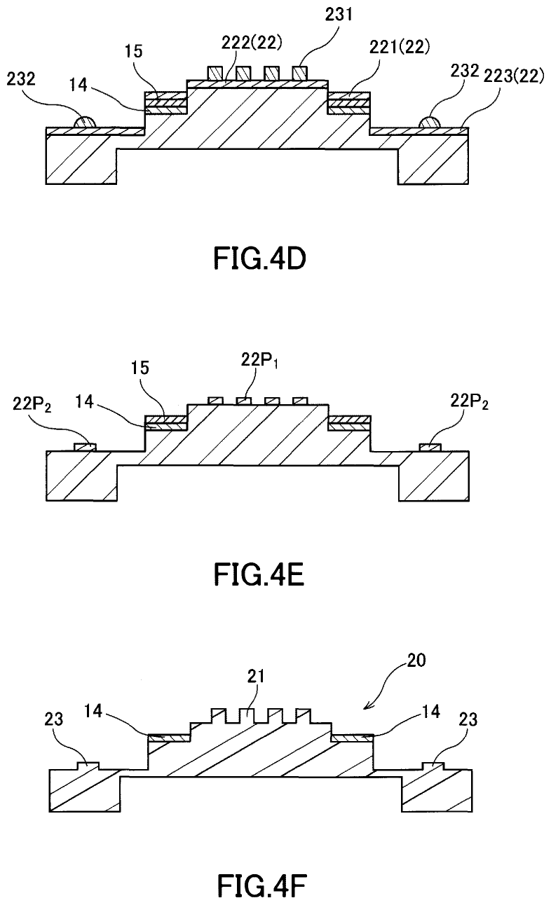

The first step structure 12 protruding from the first surface 11A of the base 11 is disposed in approximately the middle of the base 11 in plan view. The first step structure 12 has an upper surface part 12A, and a light-blocking film 14 is located on the upper surface part 12A. In the present embodiment, by having the light-blocking film 14 be located on the upper surface part 12A of the first step structure 12, only the resin into which a relief pattern 21 of the imprint mold 20 is transferred (resin directly below the second step structure 13) can be cured in the imprint process that uses the imprint mold 20 (refer to FIG. 4F) manufactured from the imprint mold substrate 10.

The second step structure 13 protruding from the upper surface part 12A of the first step structure 12 is disposed in approximately the center of the base 11 (first step structure 12) in plan view. The second step structure 13 has an upper surface part 13A, and a light-blocking film 14 is located on the upper surface part 13A. This light-blocking film 14 is removed in a subsequent step. The upper surface part 13A of the second step structure 13 constitutes a pattern region where the relief pattern 21 is formed in the imprint mold 20 (refer to FIG. 4F).

The outline shape of the upper surface part 12A of the first step structure 12 and the outline shape of the upper surface part 13A of the second step structure 13 are approximately rectangular in plan view. The size of the upper surface part 13A of the second step structure 13 is established as appropriate in correspondence to, e.g., the product that will be manufactured via an imprint process using the imprint mold 20 (refer to FIG. 4F) manufactured from the imprint mold substrate 10, and, for example, is established at about 30 mm×25 mm. The size of the outer contour of the upper surface part 12A of the first step structure 12 may be about 10 μm to 4000 μm larger than the size of the upper surface part 13A of the second step structure 13. That is, the width W12A of the upper surface part 12A of the first step structure 12 can be set at about 5 μm to 2000 μm.

The protrusion height T₁₂ of the first step structure 12 (the length parallel to the thickness direction of the base 11, between the first surface 11A of the base 11 and the upper surface part 12A of the first step structure 12) is not particularly limited as long as the goal can be accomplished of having the imprint mold substrate 10 manufactured in the present embodiment provide a first step structure 12, and, for example, it can be set at approximately 10 μm to 30 μm.

The length T₁₃ parallel to the thickness direction of the base 11 between the upper surface part 12A of the first step structure 12 and the upper surface part 13A of the second step structure 13 (the protrusion height T₁₃ of the second step structure 13) is not particularly limited and, for example, can be set at approximately 1 μm to 5 μm.

A recess 16 of prescribed size is formed in the second surface 11B of the base 11. The formation of the recess 16 makes it possible to bring about bending or flexing of the base 11, and particularly the upper surface part 13A of the second step structure 13, during the imprint process using an imprint mold 20 (refer to FIG. 4F) manufactured from an imprint mold substrate 10 manufactured according to the present embodiment and in particular during contact with the imprinted resin or during release of the imprint mold 20. As a result, the inclusion of gas between the imprinted resin and the relief pattern 21 formed in the first upper surface part 311 of a protruding structure part 3 can be suppressed when the imprinted resin is brought into contact with the upper surface part 13A of the second step structure 13 (the relief pattern 21 formed in the upper surface part 13A), and in addition the imprint mold 20 can be easily separated or released from the transfer pattern provided by the transfer of the relief pattern 21 into the imprinted resin.

The shape of the recess 16 in plan view is preferably an approximately circular shape. By using an approximately circular shape, substantially uniform bending can then be brought about, within the plane thereof, of the upper surface part 13A of the second step structure 13 of the imprint mold 20, during the imprint process and in particular when the imprinted resin is brought into contact with the upper surface part 13A of the second step structure 13 or when the imprint mold 20 is separated or released from the imprinted resin.

The size in plan view of the recess 16 is not particularly limited as long as it is a size at which the first step structure 12 is encompassed within the projection region provided by projecting the recess 16 to the side of the first surface 11A of the base 11. When this is a size at which the projection region cannot encompass the first step structure 12, the risk arises that it may not be possible to effectively bend the entire surface of the upper surface part 13A of the second step structure 13 of the imprint mold 20.

The light-blocking film 14 should be constituted of a material that can block the light (for example, UV light) that is irradiated onto the imprint mold 20 in an imprint process that uses an imprint mold 20 (refer to FIG. 4F) that has been manufactured from the imprint mold substrate 10, and this material can be exemplified by metals such as chromium, titanium, tantalum, silicon, and aluminum; chromium compounds such as chromium nitride, chromium oxide, and chromium oxynitride; tantalum compounds such as tantalum oxide, tantalum oxynitride, tantalum oxyboride, and tantalum boron oxynitride; titanium nitride; silicon nitride; and silicon oxynitride. The film thickness of the light-blocking film 14 is not particularly limited as long as the thickness is capable of blocking the aforementioned light. The light-blocking film 14 can be formed by a heretofore known method, for example, a sputtering method.

A curable resin 2 is then supplied (refer to FIG. 3B) onto the light-blocking film 14 located on the upper surface part 12A of the first step structure 12 of the multistep mold substrate 10′ and onto the light-blocking film 14 located on the upper surface part 13A of the second step structure 13, and contact is effected between a prescribed template 17 and the curable resin 2 and curing is carried out. This results in the formation of a first curable resin layer 18 on the light-blocking film 14 located on the upper surface part 12A of the first step structure 12 and in the formation of a second curable resin layer 19 on the light-blocking film 14 located on the upper surface part 13A of the second step structure 13 (refer to FIG. 3C). The template 17 is released or separated from the cured first curable resin layer 18 and second curable resin layer 19 (refer to FIG. 3D).

The first curable resin layer 18 is intended for the formation by a subsequent step of a cured film 1 functioning as a protective film 15. In the subsequent step that forms the cured film 1, the second curable resin layer 19, on the other hand, is removed and does not remain present. By executing an etching treatment on the layers formed from the curable resin 2, bonding within the inorganic component contained in the curable resin 2 is produced at the same time that desorption of the inorganic component is produced. Almost all of the inorganic component ends up undergoing desorption when the film thickness of a layer composed of the curable resin 2 is relatively thin, and the formation of a cured film 1 is thus impaired. However, by having this film thickness be relatively thick, the inorganic component bonded with other inorganic component undergoes concentration and a cured film 1 having a desired film thickness can be formed. Accordingly, the first curable resin layer 18 is formed in a film thickness that enables the formation of the cured film 1 that functions as a protective film 15, while the second curable resin layer 19 is formed in a film thickness at a size that is extinguished by the etching treatment in a subsequent step. That is, the first curable resin layer 18 and the second curable resin layer 19 are formed by supplying the curable resin 2 such that the film thickness of the second curable resin layer 19 is smaller than the film thickness of the first curable resin layer 18. Specifically, the amount of curable resin 2 supplied to the upper surface part 12A of the first step structure 12 and the amount of curable resin 2 supplied to the upper surface part 13A of the second step structure 13 may be determined using formula (1).

The method for curing the first curable resin layer 18 and the second curable resin layer 19 may be selected as appropriate in correspondence to the curing mode for the curable resin 2 that constitutes the first curable resin layer 18 and the second curable resin layer 19. For example, when the curable resin 2 is a photocuring type, the first curable resin layer 18 and the second curable resin layer 19 (curable resin 2) may be exposed to light (for example, ultraviolet radiation, electron beam, and so forth) via the template 17. If the curable resin 2 is a thermosetting type, heat may be applied to the first curable resin layer 18 and the second curable resin layer 19 (curable resin 2).

The template 17 has a protruding part 171 having a rectangular annular shape in plan view, and has a recess part 172 that is surrounded by the protruding part 171. The protruding part 171 matches the upper surface part 12A of the first step structure 12 of the multistep mold substrate 10′, and the protruding part 171—encompassed recess part 172 matches the upper surface part 13A of the second step structure 13 of the multistep mold substrate 10′. The protrusion height of the protruding part 171 may be established as appropriate such that the first curable resin layer 18 and the second curable resin layer 19 are each formed in a prescribed film thickness.

By subsequently carrying out an etching treatment on the first curable resin layer 18 and the second curable resin layer 19 (curable resin 2), the second curable resin layer 19 is removed while a cured film 1 is formed as a protective film 15 on the light-blocking film 14 located on the upper surface part 12A of the first step structure 12 (refer to FIG. 3E). The etching treatment may be a dry etching treatment (plasma treatment), in which etching is carried out in a plasma discharge atmosphere in a vacuum chamber using oxygen gas, nitrogen gas, argon gas, chlorine gas, or a gas provided by mixing two or more of these, or may be a wet etching treatment (oxidation treatment), in which the first curable resin layer 18 and the second curable resin layer 19 are brought into contact with an etching solution, e.g., sulfuric acid or aqueous hydrogen peroxide.

As described in the preceding, the film thickness of the first curable resin layer 18 is established at a size that enables the formation of a cured film 1 containing mainly inorganic component as a result of this etching treatment being able to decompose the organic component and being able to bring about bonding within the inorganic component and concentration thereof. On the other hand, the film thickness of the second curable resin layer 19 is set at a size that enables its abolition by the etching treatment. Due to this, by going through the etching treatment a cured film 1 is formed on the light-blocking film 14 that is located on the upper surface part 12A of the first step structure 12. On the other hand, the second curable resin layer 19 is removed from over the light-blocking film 14 located on the upper surface part 13A of the second step structure 13 and this light-blocking film 14 is thereby exposed.

Finally, the light-blocking film 14 located on the first surface 11A of the base 11 and the light-blocking film 14 located on the upper surface part 13A of the second step structure 13 are removed by, for example, a dry etching treatment using a chlorine-containing (Cl₂+O₂) gas (refer to FIG. 3F). A cured film 1, functioning as a protective film 15 containing mainly SiO_{X} (X is equal to or greater than 1), has been formed on the light-blocking film 14 located in the upper surface part 12A of the first step structure 12. This cured film 1 has a low reactivity versus the chlorine-containing (Cl₂+O₂) gas, which can etch the light-blocking film 14, and due to this the light-blocking film 14 located on the upper surface part 12A of the first step structure 12 can be protected. Thus, according to the present embodiment, an imprint mold substrate 10 can be manufactured in which a light-blocking film 14 and a protective film 15 are stacked in the indicated sequence on the upper surface part 12A of the first step structure 12.

This embodiment has used, as an example, a mode in which an imprint mold substrate 10 is manufactured using a multistep mold substrate 10′ in which a light-blocking film 14 is located on the upper surface part 13A of a second step structure 13; however, there are no limitations to this mode. For example, an imprint mold substrate 10 may be manufactured using a multistep mold substrate 10′ in which a light-blocking film 14 is not present on the upper surface part 13A of the second step structure 13. In this case, a second curable resin layer 19 may not be formed on the upper surface part 13A of the second step structure 13.

### [Method for Manufacturing an Imprint Mold]

The method for manufacturing an imprint mold according to the present embodiment is described in the following.

First, an imprint mold substrate 10 manufactured as shown in FIG. 3A to FIG. 3F is prepared, and a hard mask layer 22 is formed on the first surface 11A of the base 11 of the imprint mold substrate 10, on the protective film 15 located on the upper surface part 12A of the first step structure 12, and on the upper surface part 13A of the second step structure 13 (FIG. 4A). The hard mask layer 22 comprises a first hard mask layer 221 formed on the protective film 15, a second hard mask layer 222 formed on the upper surface part 13A of the second step structure 13, and a third hard mask layer 223 formed on the first surface 11A of the base 11.

The material constituting the hard mask layer 22 can be exemplified by metals such as chromium, titanium, tantalum, silicon, and aluminum; chromium compounds such as chromium nitride, chromium oxide, and chromium oxynitride; tantalum compounds such as tantalum oxide, tantalum oxynitride, tantalum oxyboride, and tantalum boron oxynitride; titanium nitride; silicon nitride; and silicon oxynitride. A single one of these may be used or a freely selected combination of two or more may be used.

The purpose of the second hard mask layer 222 is to form a mask pattern for use when an etching treatment is carried out in order to form a relief pattern 21 in the upper surface part 13A of the second step structure 13. The purpose of the third hard mask layer 223 is to form a mask pattern for use when an etching treatment is carried out in order to form an alignment mark 23 on the first surface 11A of the base 11. As a consequence, the constituent material of the hard mask layer 22 should be selected considering, e.g., the etching selectivity in conformity with the constituent material of the base 11. For example, chromium oxide, etc., can be advantageously selected as the material constituting the hard mask layer 22 when the base 11 is composed of quartz glass.

The thickness of the hard mask layer 22 is selected as appropriate considering, for example, the etching selectivity relative to the constituent material of the base 11. For example, when the base 11 is composed of quartz glass and the hard mask layer 22 is composed of chromium oxide, the thickness of the hard mask layer 22 is appropriately established in the range from approximately 0.5 nm to 200 nm.

There are no particular limitations on the method for forming the hard mask layer 22 (the first hard mask layer 221, the second hard mask layer 222, and the third hard mask layer 223), which can be exemplified by known film-formation methods such as sputtering, physical vapor deposition (PVD), and chemical vapor deposition (CVD).

Liquid droplets of an imprint resin 23 are then discretely supplied by an inkjet method onto the second hard mask layer 222 (refer to FIG. 4B). The imprint resin 23 is also dripped onto the third hard mask layer 223 (refer to FIG. 4B). The liquid droplets of the imprint resin 23 are disposed on the upper surface part 13A (second hard mask layer 222) of the second step structure 13 in correspondence to, e.g., the pattern density of the relief pattern of the master mold 24 used to form a resin pattern 231 on the second hard mask layer 222. The imprint resin 23 dripped onto the third hard mask layer 223 is disposed in correspondence to the location and size of the alignment mark 23 formed on the first surface 11A of the base 11.

The relief pattern formed in the pattern surface 24A of the master mold 24 is brought into contact with the imprint resin 23 that has been supplied onto the second hard mask layer 222, and the imprint resin 23 is thereby deployed or spread between the pattern surface 24A of the master mold 24 and the upper surface part 13A (second hard mask layer 222) of the second step structure 13. Curing is then carried out on the imprint resin 23 between the pattern surface of the master mold 24 and the upper surface part 13A (second hard mask layer 222) of the second step structure 13, and on the imprint resin 23 on the first surface 11A (third hard mask layer 223) of the base 11. This makes it possible to transfer the relief pattern of the master mold 24 into the imprint resin 23 on the second hard mask layer 222, thereby forming the resin pattern 231, and also enables the formation of a resist pattern 232 on the third hard mask layer 223 (refer to FIG. 4C).

There are no particular limitations on the imprint resin 23 (resist material), and use can be made of the resin materials (for example, ultraviolet-curing resins, thermosetting resins, etc.) that are generally used in imprint processes. The imprint resin 23 may also incorporate, for example, a release agent for facilitating separation of the master mold 24 and an adhesive for improving adherence to the upper surface part 13A (second hard mask layer 222) of the second step structure 13 of the imprint mold substrate 10.

The resin pattern 231 is then formed by separating the master mold 24 from the cured imprint resin 23 and as necessary removing the residual film part of this resin pattern 231 (refer to FIG. 4D). Proceeding in this manner enables the formation, on the second step structure 13 (second hard mask layer 222) of the imprint mold substrate 10, of a resin pattern 231 to which the relief pattern of the master mold 24 has been transferred.

Using this resin pattern 231 as a mask, for example, the second hard mask layer 222 formed on the upper surface part 13A of the second step structure 13 of the imprint mold substrate 10 is etched in a dry etching treatment using a chlorine-containing (Cl₂+O₂) etching gas, thereby forming a hard mask pattern 22P₁ (refer to FIG. 4E). At the same time as this, a hard mask pattern 22P₂ is formed by the etching of the third hard mask layer 223 with the resist pattern 232 functioning as a mask (refer to FIG. 4E). The first hard mask layer 221 located on the upper surface part 12A of the first step structure 12 is removed by the etching and the protective film 15 is thereby exposed (refer to FIG. 4E).

The imprint mold 20 is manufactured by executing a dry etching treatment on the imprint mold substrate 10 using the hard mask patterns 22P₁, 22P₂ as masks to form a relief pattern 21 on the upper surface part 13A of the second step structure 13 while forming an alignment mark 23 on the first surface 11A of the base 11 (refer to FIG. 4F). When this is done, the protective film 15, for which the main component is SiO_{X} (X is equal to or greater than 1), is removed by etching at the same time as for the imprint mold substrate 10. The dry etching of the imprint mold substrate 10 can be carried out by selecting an appropriate etching gas in conformity to the type of constituent materials in the imprint mold substrate 10. The etching gas may be, e.g., a fluorine-containing gas.

### [Method for Manufacturing a Relief Structure]

The method for manufacturing a relief structure according to the present embodiment is described in the following.

The method for manufacturing a relief structure according to the present embodiment is a method for manufacturing a relief structure that is composed of a line-and-space-shaped side wall pattern formed along a side wall of a resist pattern, and is a method for manufacturing a relief pattern by the so-called side wall method. When a relief structure is manufactured by the side wall method, in general a side wall material film is formed by, e.g., an ALD method, on the side wall of a resist pattern that becomes a core material and a side wall pattern is formed by etching this side wall material film. In this case, since the side wall pattern formed along the core material side wall assumes a loop shape (ring shape in plan view), a step referred to as loop cutting is required in order to form a line-and-space-shaped side wall pattern. The method for manufacturing a relief structure according to the present embodiment is characterized in that this step referred to as loop cutting is not necessary.

First, a substrate 31 is prepared that has a first surface 31A and a second surface 31B located on an opposite side therefrom, with a resist pattern being disposed on the first surface 31A. The resist pattern can be formed by, for example, imprint lithography using a mold, electron beam lithography using electron beam lithographic equipment, or photolithography using a photomask having prescribed openings and light-blocking areas. The resist pattern functions as a core material pattern 32 for forming the side wall pattern 36 described in the following.

When the side wall pattern 36 functions as an etching mask for etching the substrate 31, the height (thickness) of the side wall pattern 36 must be, in conformity with, e.g., the etching selectivity of the materials respectively constituting the side wall pattern 36 and the substrate 31, a height (thickness) of a size whereby the side wall pattern 36 is not extinguished during the etching treatment of the substrate 31.

On the other hand, since the core material pattern 32 is formed by slimming by submitting the resist pattern to an etching treatment, the height (thickness) of the core material pattern 32 becomes lower (thinner) than the height (thickness) of the resist pattern. Accordingly, the height (thickness) of the resist pattern must be made higher (thicker) than the height (thickness) required for the side wall pattern 36, considering, for example, the amount of slimming in the core material pattern formation step described below.

A slimming process is then executed on the resist pattern that has been formed on the first surface 31A of the substrate 31, thereby forming a core material pattern 32 provided by a thinning of the resist pattern. The slimming process on the resist pattern can be carried out, for example, using a wet etching method, dry etching method, or a combination thereof.

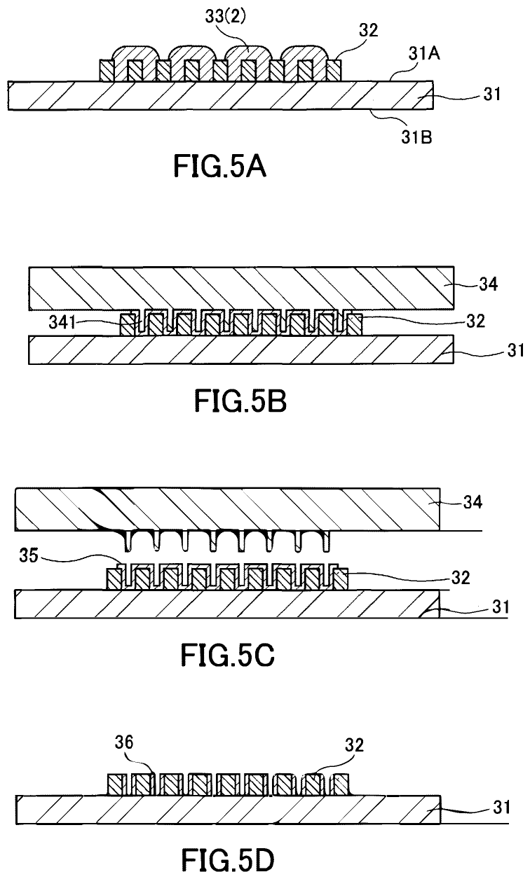

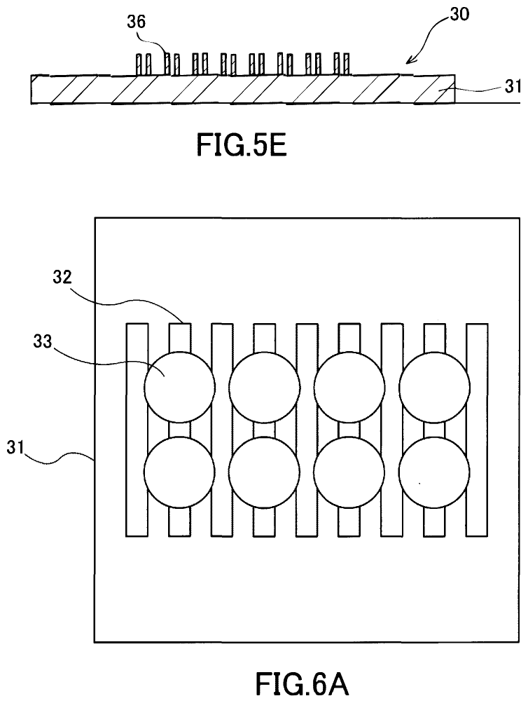

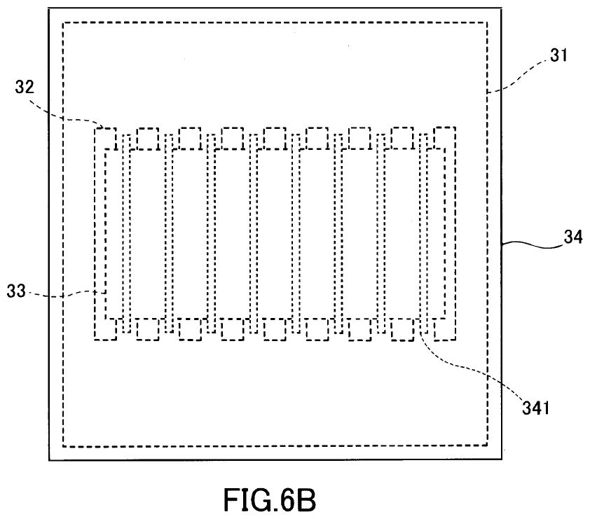

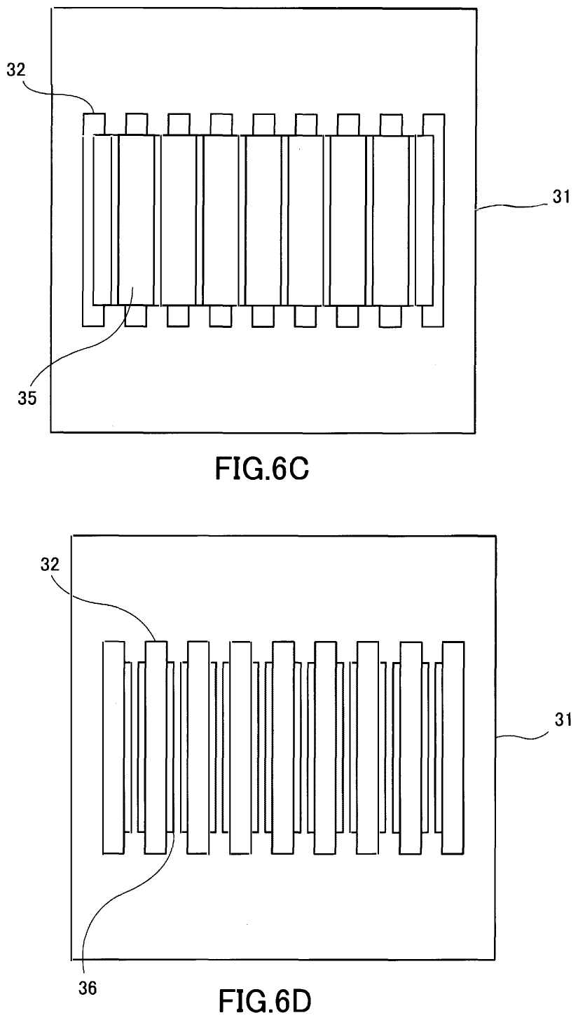

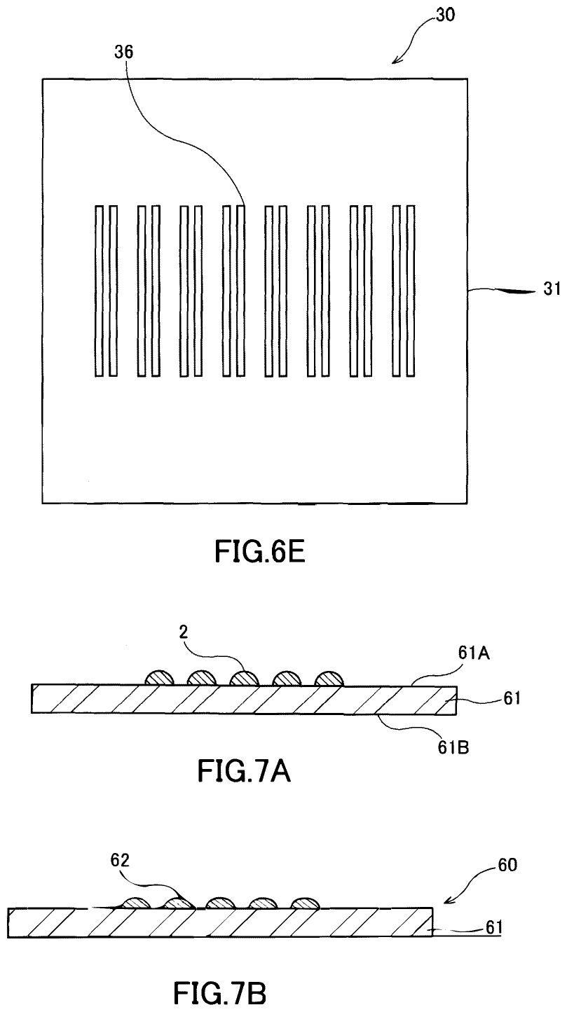

Liquid droplets of a side wall material 33 are then dripped onto the core material pattern 32 (refer to FIG. 5A and FIG. 6A). A curable resin 2 is used in the present embodiment as the side wall material 33. The number and location where the droplets of the side wall material 33 are dripped and the droplet size (amount per single droplet) may be determined such that, when the mold 34 is brought into contact with the side wall material 33 in a subsequent step, the side wall material 33 that spreads between the mold 34 and the core material pattern 32 does not completely cover the core material pattern 32 and in addition does not reach to both ends in the length direction of the core material pattern 32 at least in plan view.

A side wall material film 35 is formed (refer to FIG. 5B and FIG. 6B) by bringing a protrusion pattern 341—bearing mold 34 into contact with the liquid droplets of the side wall material 33 that have been dripped onto the core material pattern 32 and spreading the side wall material 33 between the mold 34 and the core material pattern 32, and curing the side wall material 33 while in this state. The mold 34 is thereafter separated from the cured side wall material film 35 (refer to FIG. 5C and FIG. 6C).

The protrusion pattern 341 of the mold 34 may be inserted between adjacent core material patterns 32 and should have dimensions (length of short direction in plan view) of a size that enables the formation of a prescribed space with the side walls of the core material pattern 32. By proceeding with the insertion between adjacent core material patterns 32 of a protrusion pattern 341 having such dimensions and effecting contact between the mold 34 and the side wall material 33 and curing, a side wall material film 35 can be formed that coats the side wall and top of the core material pattern 32 and that coats the first surface 31A of the substrate 31 that is exposed from between adjacent core material patterns 32.

A side wall pattern 36 is formed (refer to FIG. 5D and FIG. 6D) at the side wall of the core material pattern 32 by executing an etching treatment on the side wall material film 35 (a dry etching treatment using oxygen gas, nitrogen gas, argon gas, chlorine gas, or a gas provided by mixing two or more of the preceding). When the etching treatment is executed on the curable resin 2 that constitutes the side wall material film 35, the part that is located above the top of the core material pattern 32 is a relatively thin film and the side wall material film 35 is abolished as a consequence. In addition, the side wall material film 35 is also similarly abolished for the part located above the first surface 31A of the substrate 31 and exposed between adjacent core material patterns 32. On the other hand, the part along the side wall of the core material pattern 32 is a relatively thick film, and as a consequence the organic component is decomposed and the inorganic component undergoes bonding and concentration and a cured film 1 functioning as a side wall pattern 36 is formed.

The core material pattern 32 where the side wall pattern 36 has been formed is subsequently removed (refer to FIG. 5E and FIG. 6E) by ashing (for example, plasma ashing using an oxygen-containing gas). By doing this, only the core material pattern 32 is removed while the side wall pattern 36 can remain present on the first surface 31A of the substrate 31. Proceeding in this manner makes it possible to manufacture, on the first surface 31A of the substrate 31, a relief structure 30 in which a line-and-space-shaped side wall pattern 36 has been formed. The side wall pattern 36 may be formed on a hard mask layer (not shown) constituted of, for example, Cr, and formed on the first surface 31A of the substrate 31.

### [Method for Forming a Pattern]

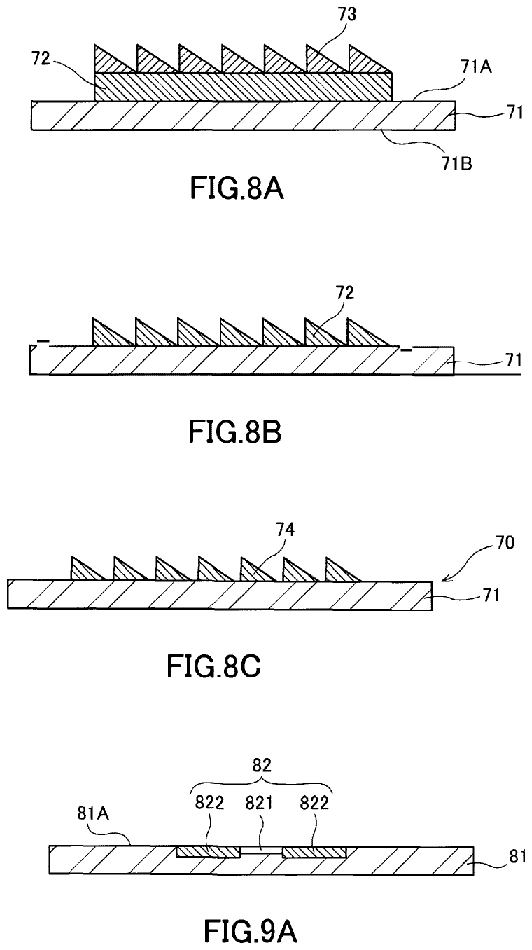

The method for forming a pattern according to the present embodiment is described in the following. The method for forming a pattern in the present embodiment will be described using the examples of a method for manufacturing a convex lens substrate (refer to FIG. 7A and FIG. 7B) and a method for manufacturing a Fresnel lens substrate (refer to FIG. 8A to FIG. 8C), but is not limited to these modes.

### [Method for Manufacturing a Convex Lens Substrate]

In the method for manufacturing a convex lens substrate 60, a substrate 61 having a first surface 61A and a second surface 61B located on an opposite side therefrom is prepared, and liquid droplets of a curable resin 2 are dripped onto the first surface 61A of the substrate 61 (refer to FIG. 7A). Since each liquid droplet of the applied curable resin 2 is intended to constitute a convex lens 62 on the convex lens substrate 60, the location of application and the size (amount of one droplet) of the liquid droplets of the curable resin 2 may be established as appropriate in conformity with the location and size of the convex lenses 62 that are required on the convex lens substrate 60 that will be manufactured.

An etching treatment (a dry etching treatment using, as the etching gas, oxygen gas, nitrogen gas, argon gas, chlorine gas, or a gas provided by mixing two or more of these, or a wet etching treatment using an etching liquid of, e.g., sulfuric acid or aqueous hydrogen peroxide) is then executed on the liquid droplets of the curable resin 2. This etching treatment can bring about decomposition of the organic component in the curable resin 2 and can produce bonding and concentration of the inorganic component and can thus form a convex lens 62 containing mainly inorganic component (refer to FIG. 7B). A convex lens substrate 60 having a convex lens 62 as the cured film 1 can be manufactured proceeding in this manner.

### [Method for Manufacturing a Fresnel Lens Substrate]

In the method for manufacturing a Fresnel lens substrate, a substrate 71 having a first surface 71A and a second surface 71B located on an opposite side therefrom is prepared, and a curable resin layer 72 comprising a curable resin 2 is formed on the first surface 71A of the substrate 71. The curable resin layer 72 can be formed, for example, by dripping liquid droplets of the curable resin 2 onto the first surface 71A of the substrate 71 and curing the curable resin 2 while contacting the curable resin 2 droplets with a flat surface-bearing mold (not shown).

A resin layer 73 having a thickness distribution (for example, a resin layer 73 having a sawtooth-shaped cross section) is formed (refer to FIG. 8A) by forming a photoresist layer on the curable resin layer 72 and, for example, executing gradation exposure at a prescribed number of gradations on the photoresist layer.

The shape of the resin layer 73 is then transferred to the curable resin layer 72 (refer to FIG. 8B) by etching the curable resin layer 72 using the resin layer 73 as a mask. A curable resin layer 72 having a sawtooth-shaped cross section is formed in the present embodiment. This etching may be, for example, a dry etching using, e.g., a fluorine-containing gas.

Finally, the curable resin layer 72 having a sawtooth-shaped cross section is subjected to a dry etching using, as the etching gas, oxygen gas, nitrogen gas, argon gas, chlorine gas, or a gas provided by mixing two or more of these, or to a wet etching using, e.g., sulfuric acid or aqueous hydrogen peroxide, as the etching liquid. This etching treatment can bring about decomposition of the organic component in the curable resin 2 and can produce bonding and concentration of the inorganic component and can thus form a Fresnel lens 74 containing mainly inorganic component (refer to FIG. 8C). A Fresnel lens substrate 70 having a Fresnel lens 74 as the cured film 1 can be manufactured proceeding in this manner.

### [Method for Manufacturing a Semiconductor Device]

The method for manufacturing a semiconductor device according to the present embodiment is described in the following.

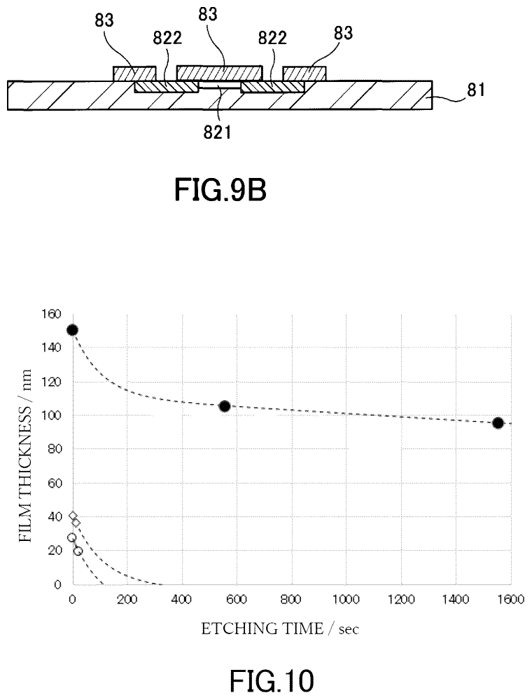

The semiconductor device manufactured in the present embodiment has a structure in which there are stacked-on a substrate having a first surface and a second surface on an opposite side therefrom—a semiconductor layer, an insulating film, and wiring on said first surface side in the indicated sequence from the first surface side. The method for manufacturing this semiconductor device contains: a step (refer to FIG. 9A) of forming, on a first surface 81A side of a substrate 81, a semiconductor layer 82 having a channel region 821 and source drain regions 822 containing a contact part that contacts the wiring; and a step (refer to FIG. 9B) of forming an insulating film 83 on an insulating film formation region that contains a channel region 821 and a region that excludes the contact parts.

The step of forming an insulating film 83 contains: a step of supplying a curable resin 2 to the insulating film formation area; a step of curing the curable resin 2; and a step of forming the insulating film 83 by decomposing the organic component in the cured curable resin 2 and causing the inorganic component to remain. According to the present embodiment, the insulating film 83 can be formed by a convenient method by curing the curable resin 2 supplied to the insulating film formation region and executing a prescribed etching treatment (a dry etching treatment using oxygen gas, nitrogen gas, argon gas, chlorine gas, or a gas provided by mixing two or more of these, or a wet etching treatment) on this curable resin 2.

The embodiments described in the preceding have been described in order to facilitate an understanding of the present invention and have not been described in order to limit the present invention. Accordingly, the import of this is that each of the elements and features disclosed in the preceding embodiments also encompasses all of the design modifications and equivalents that reside within the technical scope of the present invention.

The method for forming a cured film according to the previously described embodiment may be utilized as a method for forming a hard mask that forms a cured film 1 functioning as a hard mask layer, on the metal film of, for example, a quartz glass substrate on which a metal film, e.g., a Cr film, has been formed. Such a method for forming a hard mask may contain, for example: a step of supplying the above-described curable resin 2 onto the metal film; a step of forming a shape-receiving resin layer 5 by bringing the curable resin 2 into contact with a flat mold (for example, the mold 4 shown in FIG. 1B) and curing; and a step of forming a cured film 1 by executing a prescribed etching treatment on the shape-receiving resin layer 5 to decompose the organic component and bond·concentrate the inorganic component.

### EXAMPLES

The present invention will be described in greater detail using examples and so forth, but the present invention is in no way limited to or by the following examples and so forth.

### Example 1

A curable resin 2 was coated on a quartz glass substrate and was cured while being pressed from above with a flat mold to form a shape-receiving resin layer 5 having a film thickness of 150 nm. This shape-receiving resin layer 5 was subjected to a dry etching treatment (etching time: 1555 s) using a chlorine-containing (Cl₂+O₂) gas to form a cured film 1 having a film thickness of 95 nm. FIG. 10 shows the relationship between etching time and the film thickness (nm) of the shape-receiving resin layer 5. On the graph given in FIG. 10, the filled circle (•) gives the results of Example 1, the open diamond (⋄) gives the results for Reference Example 1, given below, and the open circle (∘) gives the results for Reference Example 2, given below. As shown in FIG. 10, once an etching time of about 300 s has passed, the change in film thickness as an exponential function is almost entirely absent. This result confirmed that a cured film 1 mainly containing inorganic component could be formed by forming a shape-receiving resin layer 5 having a prescribed initial film thickness using a curable resin 2 and carrying out a prescribed etching treatment on this shape-receiving resin layer 5 to decompose the organic component and bond·concentrate the inorganic component. The organic component contained in the shape-receiving resin layer 5 is decomposed by this dry etching treatment, while the inorganic component is not decomposed by the dry etching treatment. It is thought that mainly the organic component is decomposed in the initial stage of the dry etching treatment (for example, within 300 s from the start of the dry etching treatment). It is thought that during this time, the inorganic component undergoes bonding·concentration while a portion of the inorganic component undergoes physical etching. Due to this, the film thickness decrement of the shape-receiving resin layer 5 per unit time in the initial stage of the dry etching treatment is relatively large (refer to FIG. 10). It is thought, on the other, that after almost all of the organic component contained in the shape-receiving resin layer 5 has undergone decomposition (starting with 300 s after the start of the dry etching treatment), bonding·concentration of the inorganic component proceeds while a portion of the inorganic component undergoes physical etching. Due to this, the film thickness decrement of the shape-receiving resin layer 5 per unit time becomes relatively small (refer to FIG. 10).

With regard to the formula for the relationship between the initial film thickness T₀ of the shape-receiving resin layer 5 and the film thickness T of the cured film 1, and using Ab^{ct} for the decrement per unit time in the film thickness of the shape-receiving resin layer 5, which decrement changes in accordance with the organic component decomposition treatment time t, and using at for the decrement per unit time in the film thickness of the shape-receiving resin layer 5, which decrement does not substantially change in accordance with the decomposition treatment time t, then A—which is the film thickness decrement in the shape-receiving resin layer per unit time in the initial stage of the organic component decomposition treatment—for example, can be calculated as the amount of change per unit time, from the amount of change in the film thickness of the shape-receiving resin layer 5 when the etching treatment is executed on the shape-receiving resin layer 5 in a short period of time of not more than 30 seconds. In addition, a can be calculated as the amount of change per unit time, by continuing the etching treatment of the shape-receiving resin layer 5 and measuring the amount of change in the film thickness of the shape-receiving resin layer 5 beginning after the decrement per unit time of the film thickness of the shape-receiving resin layer 5 in accordance with the decomposition treatment time t has become substantially unchanging. b and c, which are coefficients that represent the exponential function phenomena of the film thickness of the shape-receiving resin layer 5, can be calculated by adjusting the numerical values so as to fit to the change in the film thickness of the shape-receiving resin layer 5; however, because the numerical values depend on the conditions of the decomposition treatment, the formula (1) may be derived as appropriate in conformity with, for example, the material of the shape-receiving resin layer 5 (curable resin 2), the etching treatment conditions, and so forth.

A composition containing 20 mass % of a polymerizable compound having the spherical structure as indicated below, a reactive crosslinking agent (79 mass %, dimethylsiloxane-containing difunctional acrylate), and a photopolymerization initiator (1 mass %, Omnirad 907) was used as the curable resin 2 in this Example 1. Operating in a 25° C. and 40% RH measurement environment and using an AR-G2 from TA Instruments, the curable resin was dripped onto the disk plate and a 40 mm-diameter standard steel cone was varied over a shear rate of 10 to 1000 (1/s): the viscosity of the curable resin, which was the value at 25° C. and 1000 (1/s), was 6.4 cPs, and inkjet coating was thus possible.

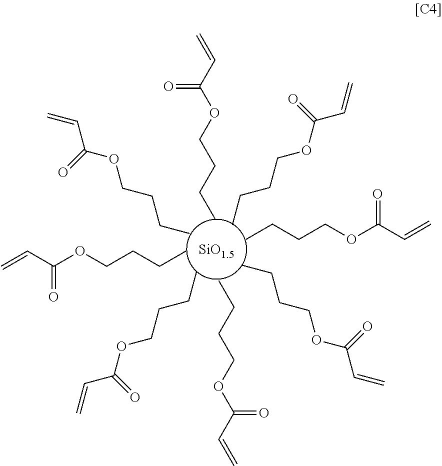

In the formula, Sio_{1.5} represents a siloxane polymerization part composed of the SiO_{3/2} unit.

This polymerizable compound was synthesized proceeding as follows.

11.7 g 3-acryloxypropyltrimethoxysilane was dissolved in 93.9 g acetone and heating to 50° C. was carried out. To this was added dropwise a mixed solution of 13.5 g ion-exchanged water and 0.07 g potassium carbonate (K₂CO₃) and stirring was performed for 5 hours at 50° C. The obtained reaction solution was washed and extracted with aqueous saturated sodium chloride and chloroform. The volatile component was removed to obtain the above-indicated polymerizable compound having a spherical structure.

### Reference Example 1

When a cured film 1 was formed proceeding as in Example 1 but changing the film thickness of the shape-receiving resin layer 5 to 40.5 nm, disappearance of the shape-receiving resin layer 5 was confirmed at an etching time of 330 s in the dry etching treatment (refer to FIG. 10).

### Reference Example 2

When a cured film 1 was formed proceeding as in Example 1 but changing the film thickness of the shape-receiving resin layer 5 to 27.3 nm, disappearance of the shape-receiving resin layer 5 was confirmed at an etching time of 120 s in the dry etching treatment (refer to FIG. 10).

### Reference Example 3

A cured film 1 was formed proceeding as in Example 1, but using as the curable resin a composition that contained 35 mass % of the above-described polymerizable compound having a spherical structure, a reactive crosslinking agent (64 mass %, dimethylsiloxane-containing difunctional acrylate), and a photopolymerization initiator (1 mass %, Omnirad 907). The change in the film thickness grew smaller faster than in Example 1, and a change in the film thickness was not seen with elapsed time (not shown). The viscosity of the curable resin, measured as in Example 1, was 20 cPs and coating by inkjet was thus possible.

### Reference Example 4

A cured film 1 was formed proceeding as in Example 1, but using as the curable resin a composition that contained 50 mass % of the above-described polymerizable compound having a spherical structure, a reactive crosslinking agent (49 mass %, dimethylsiloxane-containing difunctional acrylate), and a photopolymerization initiator (1 mass %, Omnirad 907). The change in the film thickness grew smaller even faster than in Reference Example 3, and a change in the film thickness was not seen with elapsed time (not shown). The viscosity of the curable resin, measured as in Example 1, was 54 cPs, and coating by inkjet was thus not possible and due to this coating by spin coating was carried out.

### [Example 2] Example of the Manufacture of an Imprint Mold

A multistep mold substrate 10′ composed of a quartz glass substrate and as shown in FIG. 3A was prepared; the curable resin 2 used in Example 1 was coated on the upper surface part 12A of the first step structure 12 and the upper surface part 13A of the second step structure 13; the template 17 shown in FIG. 3C was pressed onto the curable resin 2; and curing was performed by irradiating the curable resin 2 with ultraviolet radiation to form a first curable resin layer 18 and a second curable resin layer 19. The amount of supply of the curable resin 2 was adjusted based on formula (1) so as to bring the film thickness of the first curable resin layer 18 to 80 nm and the film thickness of the second curable resin layer 19 to 30 nm.

Then, by subjecting the first curable resin layer 18 and the second curable resin layer 19 to a dry etching treatment (etching time=300 s) using a chlorine-containing (Cl₂+O₂) gas, an imprint mold substrate 10 was fabricated by removing the second curable resin layer 19 and forming a cured film 1 (film thickness=40 nm), which functioned as a protective film 15, on the light-blocking film 14 located on the upper surface part 12A of the first step structure 12.

This was followed by the formation, on the first surface 11A of the base 11 of the imprint mold substrate 10, on the protective film 15 located on the upper surface part 12A of the first step structure 12, and on the upper surface part 13A of the second step structure 13, of a hard mask layer 22 composed of Cr metal (refer to FIG. 4A), and liquid droplets of an imprint resin 23 were intermittently or discretely supplied by an inkjet method onto the second hard mask layer 222 (refer to FIG. 4B). In addition, a resin pattern 231 was formed by transferring the relief pattern of the master mold 24 into the imprint resin 23 supplied onto the second hard mask layer 222, and the second hard mask layer 222 was etched, using the resin pattern 231 as a mask, to form the hard mask pattern 22P₁. The imprint mold 20 was manufactured by executing a dry etching treatment on the imprint mold substrate 10 using this hard mask pattern 22P₁ as a mask to form a relief pattern 21 on the upper surface part 13A of the second step structure 13.

### [Example 3] Example of the Manufacture of a Relief Structure by the Side Wall Method

A synthetic quartz glass substrate having a 6-inch-square outer shape and a thickness of 0.25 inch was prepared as a substrate having a first surface 31A and a second surface 31B located on a side opposite therefrom. An electron beam-sensitive resist was spin coated on the first surface 31A of this quartz glass substrate, and this resist layer was electron beam patterned and developed to form a line & space-shaped resist pattern having a pattern width of 48 nm, height of 59 nm, half pitch of 52 nm, and line length of 10 μm.

Slimming was then carried out by dry etching the resist pattern with an oxygen plasma to form a core material pattern 32 having a pattern width of 26 nm and height of 48 nm, and liquid droplets of a curable resin 2 were dripped as a side wall material 33 onto the core material pattern 32. The resin used in Example 1 was used as the curable resin 2.

A mold 34, having a protrusion pattern 341 having a pattern width of 26 nm and a height of 55 nm, was brought into contact with the liquid droplets of the curable resin 2 that had been dripped onto the core material pattern 32, thereby spreading the curable resin 2 between the mold 34 and the core material pattern 32, and a side wall material film 35 was formed by curing by irradiation with ultraviolet radiation (refer to FIG. 5B and FIG. 6B). The mold 34 was then separated from the cured side wall material film 35 (refer to FIG. 5C and FIG. 6C).

A dry etching treatment (etching time=300 s) using an etching treatment (chlorine-containing (Cl₂+O₂)) gas was executed on the side wall material film 35 to bring about decomposition of the organic component and bonding·concentration of the inorganic component and form, in the side wall of the core material pattern 32, a side wall pattern 36 having a pattern width of 26 nm and height of 23 nm (refer to FIG. 5D and FIG. 6D). The core material pattern 32 where the side wall pattern 36 was formed was then removed by plasma ashing using an oxygen-containing gas (refer to FIG. 5E and FIG. 6E) to manufacture a relief structure 30 having a line-and-space-shaped side wall pattern 36.

### [Example 4] Analysis of Surface Composition by XPS

A cured film 1 was formed proceeding as in Example 1, except that the film thickness of the shape-receiving resin layer 5 was changed to 39 nm and the dry etching treatment was run until the film thickness reached 24 nm, and surface compositional analysis on this cured film 1 was performed using X-ray photoelectron spectroscopy (XPS). Analysis of the surface composition was also carried out in the same manner by X-ray photoelectron spectroscopy (XPS) on the shape-receiving resin layer 5 prior to the dry etching treatment. These results, i.e., the compositional ratios (%) of the elements in the cured film 1 and the shape-receiving resin layer 5, were as reported in the following Table 1.

TABLE 1

| | | compositionla ratio (%) | | | |
|---|---|---|---|---|---|
| | | C | O | Si | other |
| before dry etching | surface of shape-receiving | 63 | 18 | 18 | 1 |
| treatment | resin layer | | | | |
| after dry etching | surface of cured film | 36 | 38 | 23 | 3 |
| treatment | interior of cured film | 56 | 22 | 20 | 2 |
| | (vicinity of substrate) | | | | |

(other: N etc.)

The results shown in Table 1 confirmed that the cured film formed via the dry etching treatment has a concentration gradient in which the silicon (Si) atom concentration in the vicinity of the cured film surface is higher and the silicon (Si) atom concentration towards the interior of the cured film along the thickness direction of the cured film is lower. The cured film formed via the dry etching treatment was also confirmed to have a concentration gradient in which the carbon (C) atom concentration in the vicinity of the cured film surface is lower and the carbon (C) atom concentration towards the interior of the cured film along the thickness direction of the cured film is higher.

### REFERENCE SIGNS LIST

1 Cured film
2 Curable resin
10 Imprint mold substrate
20 Imprint mold
30 Relief structure
60 Convex lens substrate
70 Fresnel lens substrate

1. A method for forming a cured film, the method comprising:
a step of supplying, to a substrate, a curable resin containing a polymerization initiator, a reactive crosslinking agent, and a polymerizable compound having in the molecule a siloxane bond and at least one polymerizable functional group;
a step of curing the curable resin; and
a step of forming a cured film by executing a plasma treatment or an oxidation treatment on the cured curable resin to decompose an organic component contained in the curable resin and cause a siloxane polymerization part to remain.

2. The method for forming a cured film according to claim 1, wherein the polymerizable compound has a spherical structure, with the siloxane polymerization part being at the center and the polymerizable functional group extending in an outward direction.

3. The method for forming a cured film according to claim 1, wherein
of oxygen atoms bonded to silicon atoms contained in the polymerizable compound, proportion of oxygen atoms bonded to a single silicon atom is not more than 10 mol %, and
the curable resin substantially does not contain a solvent and has a viscosity of not more than 20 cPs.

4. The method for forming a cured film according to claim 1, wherein a content of the reactive crosslinking agent contained in the curable resin is 49 mass % to 79 mass %.

5. The method for forming a cured film according to claim 1, wherein the step of curing the curable resin comprises: a contact step of bringing a mold into proximity to the substrate and deploying the curable resin between the substrate and the mold to form a shape-receiving resin layer; a curing step of curing the shape-receiving resin layer; and a release step of separating the mold from the cured shape-receiving layer.

6. The method for forming a cured film according to claim 5, wherein an amount of the curable resin supplied to the substrate is determined based on formula (1) below, which shows relationship among thickness T₀ of the shape-receiving resin layer, thickness T of the cured film, and decomposition treatment time t for decomposition of the organic component:
$$\begin{matrix}[ Math . 1 ] & \\ T = {T}_{0} - {\int }_{0}^{t} {Ab}^{ct} dt - α t & ( 1 )\end{matrix}$$
in formula (1), Ab^{ct} represents “the decrement per unit time in the film thickness of the shape-receiving resin layer, in which decrement changes in accordance with the decomposition treatment time t in the initial stage of the organic component decomposition treatment”; αt represents “the decrement per unit time in the film thickness of the shape-receiving resin layer, in which decrement substantially does not change in accordance with the decomposition treatment time t”; A represents “the film thickness decrement in the shape-receiving resin layer per unit time in the initial stage of the organic component decomposition treatment”; b and c are “coefficients that represent the decline as an exponential function in the film thickness of the shape-receiving resin layer”; and b>1 and c<0.

7. The method for forming a cured film according to claim 6, wherein
a cured film formation region, where the cured film is formed, and a non-cured-film-formation region, where the cured film is not formed, are established on the substrate; and
the curable resin is supplied to the cured film formation region in an amount determined so that the thickness T of the cured film based on formula (1) exceeds 0, and the curable resin is supplied to the non-cured-film-formation region in an amount determined so that the thickness T of the cured film based on formula (1) is not greater than 0.

8. The method for forming a cured film according to claim 6, wherein
the mold has a recess part-containing relief structure;
the shape-receiving resin layer has a transfer structure that contains a protruding part where the recess part of the relief structure is transferred, and has a residual film part; and
the amount of the curable resin to be supplied to the substrate is determined based on the depth of the recess part of the relief structure, the thickness of the residual film part, and formula (1).

9. The method for forming a cured film according to claim 5, wherein
the mold has a relief structure in which the minimum dimension is not more than 100 nm,
the shape-receiving layer has a transfer structure where the relief structure is transferred, and
a cured film having a pattern with a dimension smaller than the minimum dimension of the relief structure is formed.

10. The method for forming a cured film according to claim 1, wherein
the substrate has a first surface and a second surface located on an opposite side to the first surface and has, at least at the first surface, at least one material layer constituted of material different from material of the substrate; and
the curable resin is supplied onto the material layer.

11. A cured film formed by the method for forming a cured film according to claim 1, wherein, in a compositional distribution along a thickness direction of the cured film, the cured film has a concentration gradient in which silicon (Si) atom concentration is highest in the vicinity of the surface of the cured film and silicon (Si) atom concentration is lowest in the vicinity of the substrate.

12. The cured film according to claim 11, which has, in the compositional distribution along the thickness direction of the cured film, a concentration distribution in which carbon (C) atom concentration is lowest in the vicinity of the surface of the cured film and carbon (C) atom concentration is highest in the vicinity of the substrate.

13. A method for manufacturing an imprint mold substrate, the method comprising:
a step of preparing a multistep mold substrate provided with a base having a first surface and a second surface located on an opposite side to the first surface, a first step structure that protrudes from the first surface of the base, a second step structure that protrudes from an upper surface of the first step structure, and a light-blocking film that is located on an upper surface of the first step structure;
a step of supplying, onto the light-blocking film and onto an upper surface of the second step structure, a curable resin containing a polymerization initiator, a reactive crosslinking agent, and a polymerizable compound having in the molecule a siloxane bond and at least one polymerizable functional group, to form a first curable resin layer on the light-blocking film and a second curable resin layer on the upper surface of the second step structure, and then curing the first curable resin layer and the second curable resin layer; and
a step of executing a plasma treatment or oxidation treatment on the cured first curable resin layer and second curable resin layer, to decompose an organic component contained in the curable resins and cause a siloxane polymerization part to remain, thereby forming a protective layer on the light-blocking layer and removing the second curable resin layer,
wherein a thickness of the second curable resin layer is smaller than a thickness of the first curable resin layer and is a thickness of a size that can be removed during formation of the protective film.

14. The method for manufacturing an imprint mold substrate according to claim 13, comprising:
a step of forming a light-blocking material layer on the upper surface of the second step structure of the multistep mold substrate, and,
after removal of the second curable resin layer, removing the light-blocking material layer by etching.

15. A method for manufacturing an imprint mold, the method comprising:
a step of forming a first hard mask layer on the protective film of the imprint mold substrate that has been manufactured by the method according to claim 13, and forming a second hard mask layer on the upper surface of the second step structure;
a step of forming a mask pattern on the second hard mask layer;
a step of etching the second hard mask layer by using the mask pattern as a mask, to form a hard mask pattern on the upper surface of the second step structure and remove the first hard mask layer; and
a step of etching the upper surface of the second step structure by using the hard mask pattern as a mask, to form a relief pattern on the upper surface of the second step structure and remove the protective film.

16. A method for manufacturing a relief structure using the cured film formed by the cured film forming method according to claim 1, the relief structure manufacturing method comprising:
a step of preparing a substrate having a first surface and a second surface located on an opposite side to the first surface;
a step of forming, on the first surface, a protrusion pattern-bearing core material pattern;
a step of supplying the curable resin onto the core material pattern;
a step of bringing a template into contact with the curable resin supplied onto the core material pattern and effecting curing, to form a curable resin layer that coats a top and side wall of the protrusion pattern of the core material pattern and coats the first surface that is exposed from between adjacent protrusion patterns;
a step of forming the curable resin layer as the cured film, that coats the side wall of the protrusion pattern, and removing the curable resin layer that coats the top of the protrusion pattern and removing the curable resin layer that coats the first surface exposed from between adjacent protrusion patterns, so that a side wall pattern configured of the cured film is formed; and
a step of removing the core material pattern.

17. A method for forming a pattern using the cured film formed by the cured film forming method according to claim 1, the pattern forming method comprising:
a step of preparing a substrate having a first surface and a second surface located on an opposite side to the first surface;
a step of intermittently dripping the curable resin on the first surface of the substrate;
a step of curing the intermittently dripped curable resin; and
a step of forming the cured curable resin as the cured film so that a cured film pattern is formed.

18. A method for forming a pattern using the cured film formed by the cured film forming method according to claim 1, the pattern forming method comprising:
a step of preparing a substrate having a first surface and a second surface located on an opposite side to the first surface;
a step of supplying the curable resin to the first surface substrate;
a step of forming a shape-receiving resin layer by bringing a mold into proximity to the substrate and curing the curable resin deployed between the substrate and the mold;
a step of separating the mold from the shape-receiving resin layer;
a step of forming, on the shape-receiving resin layer, a resist layer that has a thickness distribution;
a step of forming a resin pattern by etching the shape-receiving resin layer by using the resist layer as a mask; and
a step of forming a cured film pattern by forming the resin pattern as the cured film.

19. A method of forming a hard mask, using the cured film formed by the cured film forming method according to claim 1, in any region on a substrate on which a metal film has been formed, the hard mask forming method comprising:
a step of supplying, the curable resin onto the metal film;
a step of forming a shape-receiving resin layer by bringing a mold into proximity to the substrate and curing the curable resin deployed between the substrate and the mold; and
a step of forming a hard mask by forming the shape-receiving resin layer as the cured film.

20. A method of forming an insulating film, using the cured film formed by the cured film forming method according to claim 1, in an insulating film formation region on a substrate, the insulating film forming method comprising:
a step of supplying, the curable resin to the insulating film formation region;
a step of curing the curable resin; and
a step of forming the insulating film by forming the cured curable resin as the cured film.

21. A method of manufacturing a semiconductor device having a structure in which, on a first surface side of a substrate having a first surface and a second surface located on an opposite side thereto, a semiconductor layer, an insulating film, and wiring are stacked in this sequence from the first surface side, the method comprising:
a step of forming, on the first surface, the semiconductor layer having source·drain regions containing a contact part that contacts the wiring; and
a step of forming the insulating film by the method according to claim 20 on the channel region and a region that excludes the contact parts.
